(19) United States
(12) Patent Application Publication
(10) Pub. No.: US 2026/0088054 A1
(43) Pub. Date: Mar. 26, 2026

(54) TIGHT PITCH CONNECTIVITY FOR DYNAMIC RANDOM ACCESS MEMORY

(71) Applicant: Intel Corporation, Santa Clara, CA (US)

(72) Inventors: Abhishek A. Sharma, Portland, OR (US); Wilfred Gomes, Portland, OR (US)

(73) Assignee: Intel Corporation, Santa Clara, CA (US)

(21) Appl. No.: 18/897,165

(22) Filed: Sep. 26, 2024

(51) Int. Cl. G11C 5/06; H01L 25/065; H10B 12/00; H10B 80/00

(52) U.S. Cl. CPC G11C 5/063; H10B 12/482; H10B 12/488; H10B 80/00; H10W 90/00; H10W 90/297

(57) ABSTRACT

Described herein are three-dimensional memory arrays that include multiple layers of memory cells. The layers are stacked and bonded to each other at bonding interfaces. The layers are formed on a support structure, such as a semiconductor wafer, that is grinded down before the layers are bonded.

Vias extend through multiple layers of memory cells, including through the support structures and bonding interfaces. Different memory layers are coupled to different interconnect regions. An interconnect pitch in an interconnect region is larger than the corresponding word-line or bit line pitch in the memory region.

### BACKGROUND

Memory arrays are typically formed over a relatively thick support structure, e.g., a semiconductor wafer. For example, access transistors for memory cells are often implemented as front end of line (FEOL) transistors on an upper-most layer of a semiconductor substrate. It is challenging to increase memory density with FEOL transistors. Decreasing critical dimensions of the memory cells requires increasing complexity and cost. Another option, processing an additional memory layer on top of a lower layer memory cells, may damage the lower level of memory cells.

### BRIEF DESCRIPTION OF THE DRAWINGS

Embodiments will be readily understood by the following detailed description in conjunction with the accompanying drawings. To facilitate this description, like reference numerals designate like structural elements.

Embodiments are illustrated by way of example, and not by way of limitation, in the figures of the accompanying drawings.

FIG. 1 is a schematic illustration of an IC device with multiple layers of memory and logic that may include a vertically stacked and bonded memory array, according to some embodiments of the present disclosure.

FIG. 2 is a schematic illustration of a plurality of memory cells, namely four memory cells, arranged in an array, according to some embodiments of the present disclosure.

FIG. 3 is a perspective view of an example three-dimensional transistor with a recessed gate, according to some embodiments of the present disclosure.

FIG. 4 is a cross-sectional view along a plane AA′ of the example arrangement shown in FIG. 3, according to some embodiments of the present disclosure.

FIG. 5 is a cross-sectional view along a plane BB′ of the example arrangement shown in FIG. 4, according to some embodiments of the present disclosure.

FIG. 6 is a cross-sectional view along a plane CC′ of the example arrangement shown in FIG. 4, according to some embodiments of the present disclosure.

FIG. 7 is a perspective view of an example array of memory cells that include three-dimensional transistors with recessed gates, according to some embodiments of the present disclosure.

FIG. 8 is a perspective view of an example vertically stacked and bonded memory array, according to some embodiments of the present disclosure.

FIG. 9 is a perspective view of an example vertically stacked and bonded memory array with a different via configuration, according to some embodiments of the present disclosure.

FIG. 10 is a top plan view of a first memory layer including a memory region and interconnect regions coupled to BLs and WLs of the memory region, according to some embodiments of the present disclosure.

FIG. 11 is a top plan view of a second memory layer including a second memory region and second interconnect regions coupled to BLs and WLs of the second memory region, according to some embodiments of the present disclosure.

FIG. 12 is a top plan view of an alternate arrangement of the second memory layer, according to some embodiments of the present disclosure.

FIG. 13 is a top plan view of a memory layer that includes interconnects arranged at larger pitches, according to some embodiments of the present disclosure.

FIG. 14 is a top plan view of an example memory layer that includes interconnects arranged at larger pitches from FIG. 13, according to some embodiments of the present disclosure.

FIG. 15 is a top plan view of interconnect regions with different interconnect sizes in different layers, according to some embodiments of the present disclosure.

FIG. 16 is a top view of a wafer and dies that include one or more DRAM layers with interconnect arrangements in accordance with any of the embodiments disclosed herein.

FIG. 17 is a cross-sectional side view of an IC device that may include one or more DRAM layers with interconnect arrangements in accordance with any of the embodiments disclosed herein.

FIG. 18 is a cross-sectional side view of an IC device assembly that may include one or more DRAM layers with interconnect arrangements in accordance with any of the embodiments disclosed herein.

FIG. 19 is a block diagram of an example computing device that may include one or more DRAM layers with interconnect arrangements in accordance with any of the embodiments disclosed herein.

### DETAILED DESCRIPTION

### Overview

The systems, methods and devices of this disclosure each have several innovative aspects, no single one of which is solely responsible for all desirable attributes disclosed herein. Details of one or more implementations of the subject matter described in this specification are set forth in the description below and the accompanying drawings.

Some memory devices may be considered “standalone” devices in that they are included in a chip that does not also include compute logic (where, as used herein, the term “compute logic devices” or simply “compute logic” or “logic devices,” refers to devices, e.g., transistors, for performing computing/processing operations). Other memory devices may be included in a chip along with compute logic and may be referred to as “embedded” memory devices. Using embedded memory to support compute logic may improve performance by bringing the memory and the compute logic closer together and eliminating interfaces that increase latency. Various embodiments of the present disclosure relate to embedded memory arrays, as well as corresponding methods and devices.

Some embodiments of the present disclosure may refer to dynamic random-access memory (DRAM) and in particular, embedded DRAM (eDRAM), because this type of memory has been introduced in the past to address the limitation in density and standby power of some other types of memory devices. However, embodiments of the present disclosure may be equally applicable to memory cells implemented other technologies. Thus, in general, memory cells described herein may be implemented as eDRAM cells, spin-transfer torque random-access memory (STTRAM) cells, resistive random-access memory (RRAM) cells, or any other non-volatile memory cells.

A memory cell, e.g., an eDRAM cell, may include a capacitor for storing a bit value, or a memory state (e.g., logical “1” or “0”) of the cell, and an access transistor controlling access to the cell (e.g., access to write information to the cell or access to read information from the cell). Such a memory cell may be referred to as a “1T-1C memory cell,” highlighting the fact that it uses one transistor (i.e., “1T” in the term “1T-1C memory cell”) and one capacitor (i.e., “1C” in the term “1T-1C memory cell”). The capacitor of a 1T-1C memory cell may be coupled to one source/drain (S/D) region/terminal of the access transistor (e.g., to the source region of the access transistor), while the other S/D region of the access transistor may be coupled to a bit-line (BL), and a gate terminal of the transistor may be coupled to a word-line (WL). Since such a memory cell can be fabricated with as little as a single access transistor, it can provide higher density and lower standby power versus some other types of memory in the same process technology, e.g., static random-access memory (SRAM).

Various 1T-1C memory cells have, conventionally, been implemented with access transistors being front end of line (FEOL), logic-process based, transistors implemented in an upper-most layer of a semiconductor substrate. Using conventional FEOL transistors creates several challenges for increasing memory density. One challenge resides in that, given a usable surface area of a substrate, there are only so many FEOL transistors that can be formed in that area, placing a limitation on the density of memory cells incorporating such transistors. In conventional solutions, attempts to increase memory density have included decreasing the critical dimensions of the 1T-1C memory cells.

Increasing the memory cell density results in reduced pitch between adjacent WLs and/or reduced pitch between adjacent BLs. This can make it challenging to form interconnects to the WLs or BLs. For example, tight interconnect pitches can lead to high capacitance between interconnect structures (e.g., between adjacent vias), which can reduce performance of the memory device. In addition, particularly if deep vias (e.g., vias that extend through multiple layers) are used to reach WLs and/or BLs, it can be difficult to achieve the same narrow pitches that, with advanced processing techniques, can be achieved within the memory arrays. As disclosed herein, interconnect regions can have interconnects at different distances from a memory array, with a staggered or stacked design.

Relatively wide vias with larger pitches may be used in layered memory devices, e.g., devices with two or more bonded memory arrays. In addition to decreasing critical dimensions within the memory arrays, e.g., by reducing transistor size, another way to improve on at least some of the challenges and issues described above is to increase the number of active memory layers, to generate a vertically stacked DRAM design using fewer masks and at a lower cost. Some embodiments of the present disclosure are based on sequentially stacked 1T-1C DRAM layers. In such embodiments, interconnects with relatively wide pitches are needed to extend through multiple bonded and stacked DRAM layers. In such embodiments, the interconnect arrangements disclosed herein can ensure that WLs and BLs of multiple DRAM layers can be accessed.

In some embodiments, multiple layers of DRAM are separately fabricated. Each layer may be fabricated on a semiconductor substrate that is thinned down after the memory cells are processed. The layers of memory are then sequentially stacked and bonded using a low-temperature bonding material, such as a bonding oxide. To control and program the memory, vias are formed through the layers of memory, including the substrates and bonding interface between adjacent layers. Because the substrates have been thinned down prior to being stacked, a via can extend through multiple layers of memory. Furthermore, for thinner substrates, a tighter via pitch (i.e., a smaller distance between neighboring vias) may be achieved. This enables adjacent rows and columns of memory cells to be closer together, and/or reduces the size of the footprint devoted to vias.

Vertically stacked 3D DRAM cells may provide several advantages and enable unique architectures that were not possible with conventional, FEOL logic transistors. Incorporating multiple layers of memory in a device may allow significantly increasing density of memory devices (e.g., density of memory cells in a memory array) having a given footprint area (the footprint area being defined as an area in a plane of the substrate, or a plane parallel to the plane of the substrate, i.e., the x-y plane of an example coordinate system shown in the drawings of the present disclosure), or, conversely, allows significantly reducing the footprint area of a structure with a given density of memory and/logic devices.

In some embodiments, the access transistors have a recessed gate, where the gate is formed in a recess of a channel material. For example, the transistors include a fin-shaped channel material having a longitudinal structure that extends parallel to an upper face of a support structure, e.g., a substrate. For each transistor, the channel material has a recessed portion, so that some part of the channel material extends higher than the recessed portion in a direction away from the support structure. Two source/drain (S/D) regions are formed in or on the channel material. A first S/D region is formed on a portion of the channel material that extends above the recessed portion, relative to the support structure. The second S/D region may be located on another portion of the channel material that extends above the recessed portion, i.e., on the other side of the recessed portion, so that both S/D regions are on a front-side of the channel material. Alternatively, the second S/D region may be located on the side of the channel material closer to the support structure, i.e., on the back-side.

A gate stack extends over the channel material and through the recessed portion. Unlike a traditional fin field-effect transistor (FinFET), where the gate stack is formed over the fin and is higher than the S/D regions relative to the support structure, in the recessed gate structure, the portion of the gate stack extending over the channel portion is closer to the support structure than the first S/D region. In a traditional FinFET, the shortest distance between the two S/D regions is a straight line that extends directly under the gate. Recessing the gate in the channel material extends the distance between the S/D regions, which reduces the leakage current between the S/D regions. For example, if the two S/D regions are both formed on the front-side of the device, the shortest path between the S/D regions is a “U” shape, with the gate stack extending through the center of the “U”.

In some embodiments, the gate fills a portion of the recess, leaving a gap between the gate and the first S/D region (and, in some embodiments, the second S/D region). In a typical FinFET structure, the channel region is directly under the gate stack, and the S/D regions are directly next to the gate stack and may extend underneath the gate stack. In this arrangement, the S/D regions may only be separated from the gate electrode by a thin layer of gate oxide, which can lead to higher leakage currents. By contrast, leaving a gap between the gate and the S/D regions helps reduce leakage currents. In other embodiments, the gate may fill the full recess, and in some embodiments, extend above the S/D regions. Extending the gate to the S/D regions reduces contact resistance, which makes it easier to turn on the transistor.

The vertically stacked and bonded memory arrays described herein may be implemented in one or more components associated with an IC or/and between various such components. In various embodiments, components associated with an IC include, for example, transistors, diodes, power sources, resistors, capacitors, inductors, sensors, transceivers, receivers, antennas, etc.

Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

For purposes of explanation, specific numbers, materials and configurations are set forth in order to provide a thorough understanding of the illustrative implementations. However, it will be apparent to one skilled in the art that the present disclosure may be practiced without the specific details or/and that the present disclosure may be practiced with only some of the described aspects. In other instances, well known features are omitted or simplified in order not to obscure the illustrative implementations.

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. The meaning of “a,” “an,” and “the” include plural references. The meaning of “in” includes “in” and “on.”

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. The terms “substantially,” “close,” “approximately,” “near,” and “about,” generally refer to being within +/−20% of a target value. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, various aspects of the illustrative implementations will be described using terms commonly employed by those skilled in the art to convey the substance of their work to others skilled in the art. For example, as used herein, a “logic state” of a ferroelectric memory cell refers to one of a finite number of states that the cell can have, e.g. logic states “1” and “0,” each state represented by a different polarization of the ferroelectric material of the cell. In another example, as used herein, a “READ” and “WRITE” memory access or operations refer to, respectively, determining/sensing a logic state of a memory cell and programming/setting a logic state of a memory cell. In other examples, the term “connected” means a direct electrical or magnetic connection between the things that are connected, without any intermediary devices, while the term “coupled” means either a direct electrical or magnetic connection between the things that are connected or an indirect connection through one or more passive or active intermediary devices. The term “circuit” means one or more passive and/or active components that are arranged to cooperate with one another to provide a desired function. In yet another example, a “high-k dielectric” refers to a material having a higher dielectric constant (k) than silicon oxide. The terms “oxide,” “carbide,” “nitride,” etc. refer to compounds containing, respectively, oxygen, carbon, nitrogen, etc.

### Example IC With Vertically Stacked and Bonded Memory Layers

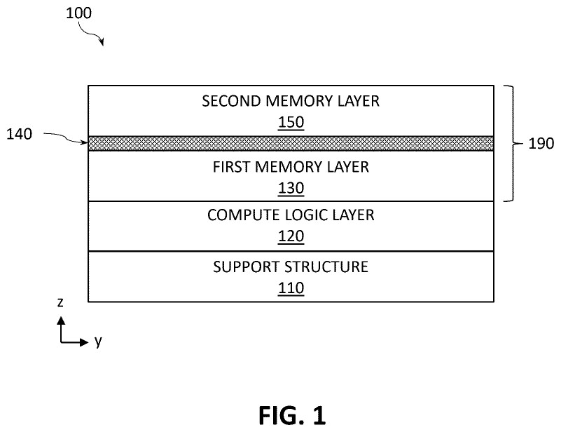

FIG. 1 provides a schematic illustration of an IC device 100 with logic and multiple memory layers that may be sequentially stacked and bonded, according to some embodiments of the present disclosure. As shown in FIG. 1, in general, the IC device 100 may include a support structure 110, a compute logic layer 120, and a memory array 190 that includes a first memory layer 130 and a second memory layer 150.

The second memory layer 150 is bonded to the first memory layer 130 at a bonding interface 140 that includes a bonding material. The bonding interface 140 may further include signal and/or power interconnects between the first memory layer 130 and the second memory layer 150. The memory array 190 may include additional memories stacked above the second memory layer 150 and connected in a similar manner, e.g., a third memory layer may be stacked above the second memory layer 150 and bonded to the second memory layer 150 by a second bonding interface similar to the bonding interface 140. The first memory layer 130 may be bonded to the compute logic layer by an additional bonding interface.

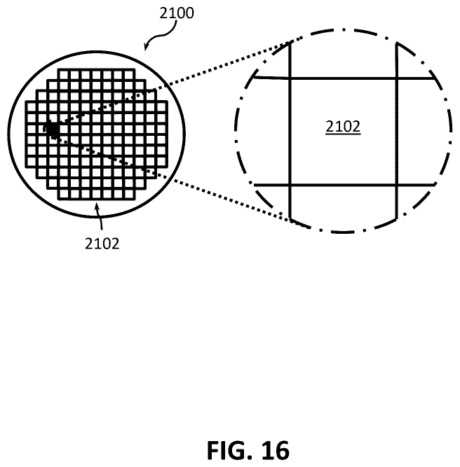

Implementations of the present disclosure may be formed or carried out on the support structure 110, which may be, e.g., a substrate, a die, a wafer or a chip. The support structure 110 may, e.g., be the wafer 2100 of FIG. 16, discussed below, and may be, or be included in, a die, e.g., the singulated die 2102 of FIG. 16, discussed below. The support structure 110 may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. In some embodiments, the support structure 110 may be a printed circuit board (PCB) substrate. Although a few examples of materials from which the substrate may be formed are described here, any material that may serve as a foundation upon which a semiconductor device implementing any of the vertically stacked and bonded memory arrays as described herein may be built falls within the spirit and scope of the present disclosure.

The first and second memory layers 130, 150 may, together, be seen as forming a memory array 190. As such, the memory array 190 may include access transistors, capacitors, as well as WLs (e.g., row selectors) and BLs (e.g., column selectors), making up memory cells. Each memory layer 130, 150 may have a memory region (e.g., a region including the memory array) and an interconnect portion (e.g., a region including interconnect structures coupled to WLs and BLs). The compute logic layer 120 may include various logic layers, circuits, and devices (e.g., logic transistors) to drive and control a logic IC. For example, the logic devices of the compute logic layer 120 may form a memory peripheral circuit to control (e.g., access (read/write), store, refresh) the memory cells of the memory array 190.

In some embodiments, the compute logic layer 120 may be provided in a FEOL layer with respect to the support structure 110. In some embodiments, the compute logic layer 120 may be provided in a FEOL and in one or more lowest BEOL layers (i.e., in one or more BEOL layers which are closest to the support structure 110), while the first memory layer 130 and the second memory layer 150 may be seen as provided in respective BEOL layers. Various BEOL layers may be, or include, metal layers. Various metal layers of the BEOL may be used to interconnect the various inputs and outputs of the logic devices in the compute logic layer 120 and/or of the memory cells in the memory layers 130, 150. In particular, these metal layers may connect to through-silicon vias (TSVs) that couple the compute logic layer 120 to the first memory layer 130, the first memory layer 130 to the second memory layer 150, and/or the compute logic layer 120 to the second memory layer 150.

Generally speaking, each of the metal layers of the BEOL may include a via portion and a trench/interconnect portion. The trench portion of a metal layer is configured for transferring signals and power along electrically conductive (e.g., metal) lines (also sometimes referred to as “trenches”) extending in the x-y plane (e.g., in the x-or y-directions), while the via portion of a metal layer is configured for transferring signals and power through electrically conductive vias extending in the z-direction, e.g., to any of the adjacent metal layers above or below. Accordingly, vias connect metal structures (e.g., metal lines or vias) from one metal layer to metal structures of an adjacent metal layer. While referred to as “metal” layers, various layers of the BEOL may include only certain patterns of conductive metals, e.g., copper (Cu), aluminum (Al), tungsten (W), or cobalt (Co), or metal alloys, or more generally, patterns of an electrically conductive material, formed in an insulating medium such as an ILD. The insulating medium may include any suitable ILD materials such as silicon oxide, carbon-doped silicon oxide, silicon carbide, silicon nitride, aluminum oxide, and/or silicon oxynitride.

As noted above, the vias may include power vias for transferring power between layers and signal vias for transferring data signals between layers. In general, cross-sectional dimensions (e.g., diameters) and a pitch (e.g., defined as a center-to-center distance) of power vias are larger than cross-sectional dimensions and a pitch of signal vias. After vias are formed in a particular IC structure (e.g., the compute logic layer 120 or the first memory layer 130), the faces of the IC structures that are joined at the bonding interface may be grinded so that electrical connections can be made between vias of adjoining IC structures. Grinding a face of an IC structure to reveal the vias may be performed using any suitable thinning/polishing processes as known in the art. In some embodiments, at least a portion of vias extending through the memory layers 130 and 150 may be formed after the memory layers 130 and 150 have been bonded together, e.g., after the second memory layer 150 has been bonded to the first memory layer 130 at the bonding interface 140.

The first memory layer 130 is physically bonded to the second memory layer 150 at the bonding interface 140. Additional memory layers may be sequentially bonded, e.g., above the second memory layer 150. For example, an upper face of the first memory layer 130 (e.g., the face opposite the support structure 110) is bonded to a lower face of the second memory layer 150. The bonding may be performed using insulator-insulator bonding, e.g., as oxide-oxide bonding, where an insulating material of a first IC structure (e.g., the first memory layer 130) is bonded to an insulating material of a second IC structure (e.g., the second memory layer 150). In some embodiments, a bonding material may be present in between the faces of the first and second IC structures that are bonded together. To bond two IC structures together, the bonding material may be applied to one or both faces of the first and second IC structures that should be bonded. For example, the bonding material making up the bonding interface 140 is applied to the upper face of the first memory layer 130 and/or the lower face of the second memory layer 150. After the bonding material is applied, the first and second IC structures are put together, possibly while applying a suitable pressure and heating up the assembly to a suitable temperature (e.g., to relatively low temperatures, e.g., between about 50 and 200 degrees Celsius) for a duration of time. In some embodiments, the bonding material may be an adhesive material that ensures attachment of the first and second IC structures to one another. In some embodiments, the bonding material may be an etch-stop material. In some embodiments, the bonding material may be both an etch-stop material and have suitable adhesive properties to ensure attachment of the first and second IC structures to one another.

In some embodiments, the bonding material may include silicon, nitrogen, and carbon, where the atomic percentage of any of these materials may be at least 1%, e.g., between about 1% and 50%, indicating that these elements are added deliberately, as opposed to being accidental impurities which are typically in concentration below about 0.1%. Having both nitrogen and carbon in these concentrations in addition to silicon is not typically used in conventional semiconductor manufacturing processes where, typically, either nitrogen or carbon is used in combination with silicon, and, therefore, could be a characteristic feature of the hybrid bonding. Using an etch-stop material at a bonding interface that includes include silicon, nitrogen, and carbon, where the atomic percentage of any of these materials may be at least 1%, e.g., SiOCN, may be advantageous in terms that such a material may act both as an etch-stop material, and have sufficient adhesive properties to bond the first and second IC structures together. In addition, an etch-stop material at the interface between the first and second IC structures that includes include silicon, nitrogen, and carbon, where the atomic percentage of any of these materials may be at least 1%, may be advantageous in terms of improving etch-selectivity of this material with respect to etch-stop materials that may be used in different of the first and second IC structures.

In some embodiments, no bonding material may be used, but there will still be a bonding interface resulting from the bonding of the IC structures to one another. Such a bonding interface may be recognizable as a seam or a thin layer in the microelectronic assembly, using, e.g., selective area diffraction (SED), even when the specific materials of the insulators of the first and second IC structures that are bonded together may be the same, in which case the bonding interface would still be noticeable as a seam or a thin layer in what otherwise appears as a bulk insulator (e.g., bulk oxide) layer. In different embodiments, the bonding interface 140 and bonding interfaces for additional memory layers and/or a bonding interface between the compute logic layer 120 and the first memory layer 130 may be the same or different, and the bonding process may be the same or different. For example, a first bonding material bonds the first memory layer 130 to the second memory layer 150 at the bonding interface 140, and a second, different bonding material bonds the first memory layer 130 to the compute logic layer 120.

In other embodiments of the IC device 100, compute logic devices may be provided in a layer above the memory array 190, in between memory layers 130, 150, or combined with the memory layers 130, 150. The layers of memory and compute logic devices may be bonded using a bonding interface similar to the bonding interface 140 described above.

The illustration of FIG. 1 is intended to provide a general orientation and arrangement of various layers with respect to one another, and, unless specified otherwise in the present disclosure, includes embodiments of the IC device 100 where portions of elements described with respect to one of the layers shown in FIG. 1 may extend into one or more, or be present in, other layers.

### Example 1T-1C Memory Array

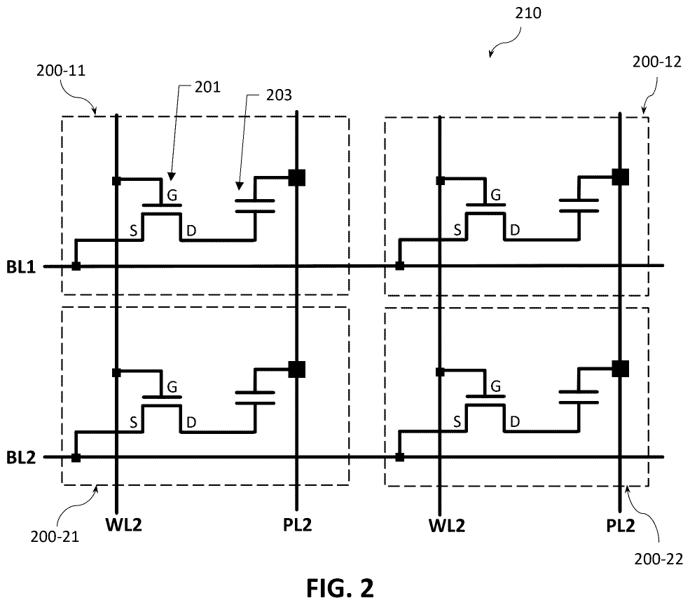

FIG. 2 provides a schematic illustration of a plurality of 1T-1C memory cells 200, namely four cells, arranged in an array 210, according to some embodiments of the present disclosure. Each 1T-1C memory cell 200 is illustrated in FIG. 2 to be within a dashed box labeled 200-11, 200-12, 200-21, and 200-22. The 1T-1C memory cell 200-11 may include an access transistor 201 and a capacitor 203. The access transistor 201 has a gate terminal, a source terminal, and a drain terminal, indicated in the example of FIG. 2 as terminals G, S, and D, respectively. Each of the other memory cells 200-12, 200-21, and 200-22 includes a transistor and capacitor, similar to the transistor 201 and capacitor 203 and similarly arranged.

In each 1T-1C memory cell 200, the gate terminal of the access transistor 201 is coupled to a word-line (WL), one of the source or drain terminals of the access transistor 201 is coupled to a bit-line (BL), and the other one of the source or drain terminals of the access transistor 201 is coupled to a first electrode of the capacitor 203. The other electrode of the capacitor 203 is coupled to a plate-line (PL). The WL, BL, and PL are used together to read and program the capacitor 203. In the following, the electrode of the capacitor 203 coupled to the PL is referred to as a “first capacitor electrode” while the electrode of the capacitor 203 coupled to the access transistor is referred to as a “second capacitor electrode.”

As is commonly known, source and drain terminals are interchangeable in transistors. Therefore, while the example of FIG. 2 illustrates that the transistor 201 is coupled to the capacitor 203 by its drain terminal, in other embodiments, any one of a source or a drain terminal of the transistor 201 may be coupled to the second electrode of the capacitor 203. A source and a drain terminal of a transistor is sometimes referred to in the following as a “transistor terminal pair” and a “first terminal” of a transistor terminal pair is used to describe, for the access transistor 201, the terminal that is connected to the BL, while a “second terminal” is used to describe the source or drain terminal of the access transistor that is connected to the second capacitor electrode of the capacitor 203.

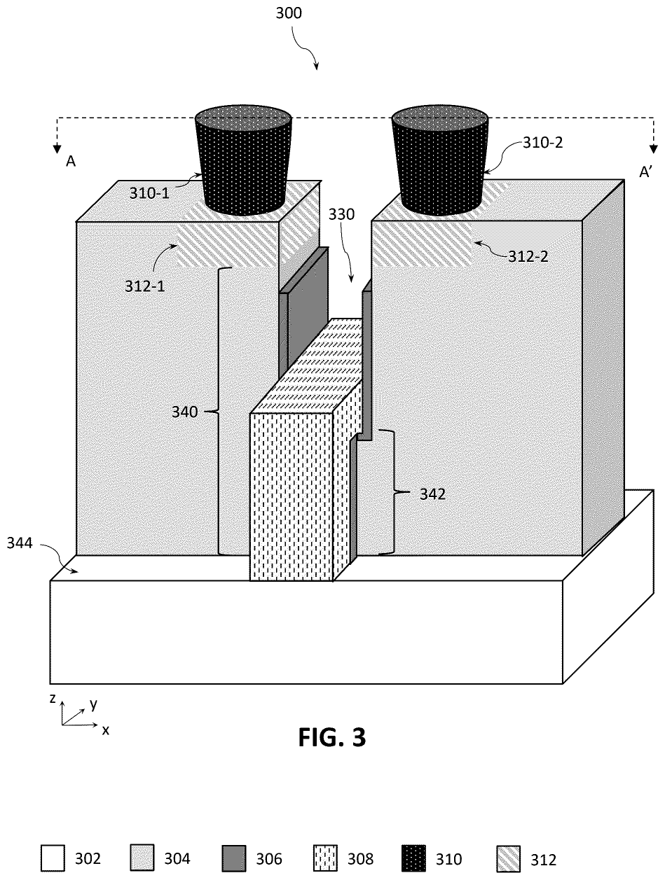

In various embodiments, the access transistor 201 may be any metal oxide semiconductor (MOS) transistors which include drain, source, and gate terminals. In particular embodiments of the present disclosure, the access transistor 201 is a three-dimensional transistor with a recessed gate, such as any of the transistors illustrated in FIGS. 3-11.

While the array 210 shown in FIG. 2 has four such memory cells 200, in other embodiments, the array 210 may, and typically would, include many more memory cells. Furthermore, in other embodiments, the 1T-1C memory cells as described herein may be arranged in arrays in other manners as known in the art, all of which being within the scope of the present disclosure.

FIG. 2 illustrates that BL can be shared among multiple memory cells 200 in a column, and that WL and PL can be shared among multiple memory cells 200 in a row. As is conventionally used in context of memory, the terms “row” and “column” do not reflect the, respectively, horizontal and vertical orientation on a page of a drawing illustrating a memory array but, instead, reflect on how individual memory cells are addressed. Namely, memory cells 200 sharing a single BL are said to be in the same column, while memory cells 200 sharing a single WL are said to be on the same row. Thus, in FIG. 2, the horizontal lines refer to columns while vertical lines refer to rows. Different instances of each line (BL, WL, and PL) are indicated in FIG. 2 with different reference numerals, e.g. BL1 and BL2 are the two different instances of the BL as described herein. The same reference numeral on the different lines WL and PL indicates that those lines are used to address/control the memory cells in a single row, e.g. WL1 and PL1 are used to address/control the memory cells 200 in row 1, and so on. Each memory cell 200 may then be addressed by using the BL corresponding to the column of the cell and by using the WL and PL corresponding to the row of the cell. For example, the memory cell 200-11 is controlled by BL1, WL1, and PL1, the memory cell 200-12 is controlled by BL1, WL2, and PL2, and so on.

### Example Three-Dimensional Transistor With Recessed Gate

In a conventional FinFET, a channel region extends straight under a gate stack, such that the shortest path between the source and drain regions is a straight line directly under the gate oxide. Lengthening the path between the source and drain regions, e.g., moving the source and drain regions further apart, can reduce leakage current. While a conventional FinFET could be stretched in the direction of the fin to increase the channel length, this would increase the size of the transistor and, in an IC device consisting of many such transistors, would reduce transistor density across the device, which is undesirable. A three-dimensional transistor with a recessed gate, such as the transistor arrangement shown in FIG. 3, provides a longer channel length between a source and drain region while maintaining transistor density across a device. The recessed gate structure results in a longer path between the source and drain regions, which reduces leakage current.

FIG. 3 is a perspective view of an example three-dimensional transistor 300 with a recessed gate, according to some embodiments of the present disclosure. As shown, the transistor 300 is formed on a support structure 302, and the transistor 300 includes a channel material 304, a gate stack comprising a gate dielectric 306 (which could include a stack of one or more gate dielectric materials), and a gate electrode 308 (which could include a stack of one or more gate electrode materials). The channel material 304 has a recess 330, and the gate stack extends through the recess 330. In this example, two source/drain (S/D) regions 312 are formed on either side of the recess 330 and above the gate electrode 308. A pair of contact electrodes 310 are coupled to the S/D regions 312.

A number of elements referred to in the description of FIGS. 3-9 with reference numerals are illustrated in these figures with different patterns, with a legend showing the correspondence between the reference numerals and patterns being provided at the bottom or side of each drawing page containing FIGS. 3-9. For example, the legend in FIG. 3 illustrates that FIG. 3 uses different patterns to show a support structure 302, a channel material 304, a gate dielectric 306, a gate electrode 308, a contact electrode 310, and a S/D region 312.

The support structure 302 may include any such substrate that provides a suitable surface for providing the transistor 300. Various types of support structures are described with respect to the support structure 110. In some embodiments, one or more additional layers not shown in FIG. 3 are situated between the support structure 302 and the channel material 304. In some embodiments, the support structure 302 for the transistor 300 is different from but similar to the support structure 110, e.g., the compute logic layer 120 is formed on one support structure 110, and a memory layer (e.g., the first memory layer 130 and/or the second memory layer 150) include transistors, such as the transistor 300, formed on a second support structure 302 that may be similar to or different from the support structure 110.

In some embodiments, the channel material 304 may be composed of semiconductor material systems including, for example, N-type or P-type materials systems. In some embodiments, the channel material 304 may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the channel material 304 may include a combination of semiconductor materials where one semiconductor material may be used for the channel portion, and another material, sometimes referred to as a “blocking material,” may be used between the channel portion and the support structure 302 over which the transistor 300 is provided. In some embodiments, the channel material 304 may include a monocrystalline semiconductor, such as silicon (Si) or germanium (Ge). In some embodiments, the channel material 304 may include a compound semiconductor with a first sub-lattice of at least one element from group III of the periodic table (e.g., Al, Ga, In), and a second sub-lattice of at least one element of group V of the periodic table (e.g., P, As, Sb). In some embodiments, the channel material 304 is an epitaxial semiconductor material deposited on the support structure 302 using an epitaxial deposition process. The epitaxial semiconductor material may have a polycrystalline structure with a grain size between about 2 nanometers and 100 nanometers, including all values and ranges therein.

For some example N-type transistor embodiments (i.e., for the embodiments where the transistor 300 is an N-type metal-oxide-semiconductor (NMOS)), the channel material 304 may advantageously include a III-V material having a high electron mobility, such as, but not limited to InGaAs, InP, InSb, and InAs. For some such embodiments, the channel material 304 may be a ternary III-V alloy, such as InGaAs, GaAsSb, InAsP, or InPSb. For some InₓGa₁₋ₓAs fin embodiments, In content (x) may be between 0.6 and 0.9, and may advantageously be at least 0.7 (e.g., In_{0.7}Ga_{0.3}As). In some embodiments with highest mobility, the channel material 304 may be an intrinsic III-V material, i.e., a III-V semiconductor material not intentionally doped with any electrically active impurity. In alternate embodiments, a nominal impurity dopant level may be present within the channel material 304, for example to further fine-tune a threshold voltage Vt, or to provide HALO pocket implants, etc. Even for impurity-doped embodiments however, impurity dopant level within the channel material 304 may be relatively low, for example below 10¹⁵ dopant atoms per cubic centimeter (cm⁻³), and advantageously below 10¹³ cm⁻³.

For some example P-type transistor embodiments (i.e., for the embodiments where the transistor 300 is a P-type metal-oxide-semiconductor (PMOS)), the channel material 304 may advantageously be a group IV material having a high hole mobility, such as, but not limited to Ge or a Ge-rich SiGe alloy. For some example embodiments, the channel material 304 may have a Ge content between 0.6 and 0.9, and advantageously may be at least 0.7. In some embodiments with highest mobility, the channel material 304 may be intrinsic III-V (or IV for P-type devices) material and not intentionally doped with any electrically active impurity. In alternate embodiments, one or more a nominal impurity dopant level may be present within the channel material 304, for example to further set a threshold voltage (Vt), or to provide HALO pocket implants, etc. Even for impurity-doped embodiments however, impurity dopant level within the channel portion is relatively low, for example below 10¹⁵ cm⁻³, and advantageously below 10¹³ cm⁻³.

In some embodiments, the transistor 300 may be a thin film transistor (TFT). A TFT is a special kind of a field-effect transistor made by depositing a thin film of an active semiconductor material, as well as a dielectric layer and metallic contacts, over a supporting layer that may be a non-conducting layer. At least a portion of the active semiconductor material forms a channel of the TFT. If the transistor 300 is a TFT, the channel material 304 may include a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, if the transistor 300 is a TFT, the channel material 304 may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N-or P-type amorphous or polycrystalline silicon, germanium, indium gallium arsenide, silicon germanium, gallium nitride, aluminum gallium nitride, indium phosphite, and black phosphorus, each of which may possibly be doped with one or more of gallium, indium, aluminum, fluorine, boron, phosphorus, arsenic, nitrogen, tantalum, tungsten, and magnesium, etc. In some embodiments, the channel material 304 may have a thickness between about 5 and 75 nanometers, including all values and ranges therein. In some embodiments, a thin film channel material 304 may be deposited at relatively low temperatures, which allows depositing the channel material 304 within the thermal budgets imposed on back end fabrication to avoid damaging other components, e.g., front end components such as the logic devices.

The channel material 304 has a fin shape that extends away from the support structure 302 in a direction substantially perpendicular to the support structure 302, i.e., perpendicular to the upper face 344 of the support structure 302 and extending in the z-direction in the exemplary reference coordinate system x-y-z shown in FIG. 3. The channel material 304 further has a longitudinal structure extending in a direction parallel to a plane of the support structure 302, e.g., parallel to the upper face 344 of the support structure 302 and extending in the x-direction in the exemplary reference coordinate system x-y-z shown in FIG. 3. The fin may extend further in the x-direction than shown in FIG. 3; for example, many transistors similar to the transistor 300 may be formed along a fin that extends in the x-direction. Channel material 304 for individual transistors may be formed from the fin, e.g., portions of the fin for different transistors may be individuated by patterning and etching the fin, and depositing an ILD material between the portions.

As shown in FIG. 3, a recess 330 extends into the channel material 304 in the z-direction. The recess 330 does not extend all the way through the channel material 304 in the z-direction, i.e., the recess 330 does not extend down to the support structure 302. The recess 330 extends through the channel material 304 in the y-direction. The recess 330 may be formed in the channel material 304 using an etching process. For example, the channel material 304 may be patterned using any suitable patterning techniques, e.g., photolithographic or electron-beam patterning, possibly in combination with using a mask, e.g., a hardmask, and a suitable etching process is used to remove portions of the channel material 304, e.g., using dry etch, wet etch, reactive ion etch (RIE), ion milling, etc. In some embodiments, an ILD layer (not shown in FIG. 3) is deposited over the patterned channel material 304, and the ILD layer is patterned prior to etching. In such embodiments, the ILD layer is etched, and then the recess 330 in the channel material 304 is etched. In some embodiments, a mask layer is between the channel material 304 and the ILD layer; in such embodiments, the ILD layer is etched, and then the mask layer (which may have been previously patterned) is etched, and then the channel material 304 is etched to form the recess 330.

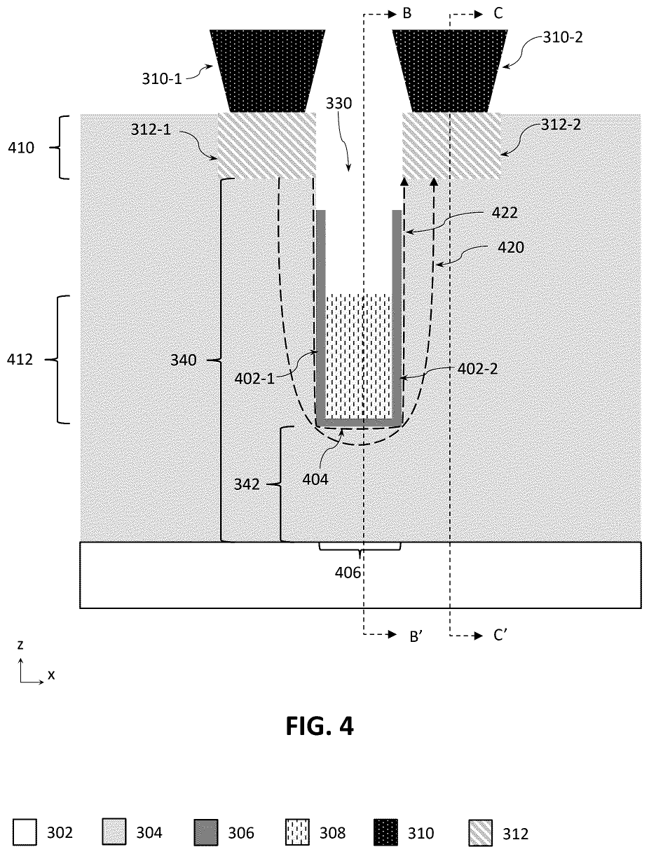

FIG. 4 illustrates a cross-sectional side view in the x-z plane of the example coordinate system x-y-z shown in FIG. 3, with the cross section of FIG. 4 taken across the fin of channel material 304 (e.g., along the plane shown in FIG. 3 as a plane AA′). As shown in FIG. 4, the recess 330 includes two sidewalls 402-1 and 402-2, and a base 404. While the sidewalls 402 and base 404 are illustrated as being at right angles with sharp corners, the cross-sectional shape of the recess 330 may have a different shape, e.g., the base 404 or a portion of the base 404 may be curved, e.g., the base 404 has a semicircular cross section connected to straight sidewalls 402-1 and 402-2, or the recess 330 has a parabolic cross section with a lower portion of the parabola referred to as the base 404 and the upper portions of the parabola referred to as the sidewalls 402.

FIG. 4 also illustrates a portion 406 of the channel material 304 is under the recess 330. This portion 406 is situated between the gate stack (specifically, the portion of the gate stack that extends over the channel material 304) and the support structure 302.

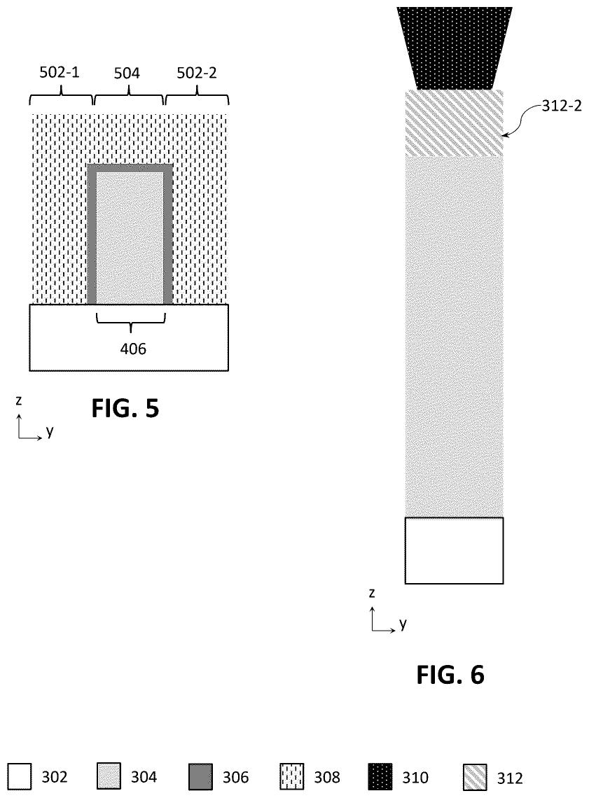

Returning to FIG. 3, the gate stack extends through the recess 330 in the y-direction. The gate stack wraps around the channel material 304, so that one portion of the gate stack on either side of the channel material 304 is directly over the support structure 302, without the channel material 304 between these portions of the gate stack and the support structure 302. FIG. 5 illustrates a cross-sectional view in the y-z plane of the example coordinate system shown in FIG. 3, with the cross section taken along the gate stack (e.g., along the plane shown in FIG. 4 as a plane BB′). FIG. 5 illustrates three portions of the gate stack: two portions 502-1 and 502-2 on either side of the channel material 304, and another portion 504 over the portion 406 of the channel material described above and illustrated in the x-z plane in FIG. 4. The portion 504 of the gate stack extending over the portion 406 of the channel material 304 is situated in the recess 330.

The gate stack includes a gate dielectric 306 and a gate electrode 308. In some embodiments, the gate dielectric 306 may include one or more high-k dielectrics. Examples of high-k materials that may be used in the gate dielectric 306 may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. The gate dielectric 306 may be deposited using a conformal deposition process, such as atomic layer deposition (ALD) or chemical vapor deposition (CVD). Conformal deposition generally refers to deposition of a certain coating on any exposed surface of a given structure. A conformal coating may, therefore, be understood as a coating that is applied to exposed surfaces of a given structure, and not, for example, just to the horizontal surfaces. In some embodiments, an annealing process may be carried out on the gate dielectric 306 during manufacture of the transistor 300 to improve the quality of the gate dielectric 306. The gate dielectric 306 may have a thickness, a dimension measured in the direction of the y-axis of the reference coordinate system x-y-z shown in FIG. 3, that may, in some embodiments, be between 0.5 nanometers and 20 nanometers, including all values and ranges therein (e.g., between 2 and 6 nanometers).

The gate electrode 308 may include at least one P-type work function metal or N-type work function metal, depending on whether the transistor 300 is a PMOS transistor or an NMOS transistor (P-type work function metal used as the gate electrode 308 when the transistor 300 is a PMOS transistor and N-type work function metal used as the gate electrode 308 when the transistor 300 is an NMOS transistor). For a PMOS transistor, metals that may be used for the gate electrode 308 may include, but are not limited to, ruthenium, palladium, platinum, cobalt, nickel, and conductive metal oxides (e.g., ruthenium oxide). For an NMOS transistor, metals that may be used for the gate electrode 308 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode 308 may consist of a stack of two or more metal layers, where one or more metal layers are work function metal layers and at least one metal layer is a fill metal layer. Further layers may be included next to the gate electrode 308 for other purposes, such as to act as a diffusion barrier layer or/and an adhesion layer.

In the example shown in FIGS. 3-5, the gate stack extends partway up the recess 330, with a gap between the top of the gate stack and the top of the channel material 304. As illustrated in FIG. 4, the gate dielectric 306 is deposited along the base 404 and along a portion of each of the two sidewalls 402-1 and 402-2. The gate electrode 308 is deposited within the recess 330, with the gate dielectric 306 between the gate electrode 308 and the channel material 304. In the example of FIGS. 3-5, the gate dielectric 306 extends up the sidewalls 402-1 and 402-2 in the z-direction towards the S/D regions 312, but not reaching the S/D regions 312. The gate electrode 308 and gate dielectric 306 may have different heights, and different relative heights in the z-direction, than the example shown in FIGS. 3 and 4 as long as the gate dielectric 306 is between the gate electrode 308 and the channel material 304, so that the gate electrode 308 is not in contact with the channel material 304 and/or S/D regions 312. For example, the gate dielectric 306 and gate electrode 308 may both extend in the z-direction up to the base of the S/D regions 312. In another example, the gate dielectric 306 and gate electrode 308 extend along the full length of the sidewalls 402 to a top face of the channel material 304. In some embodiments, the gate electrode 308 further extends above the top face of the channel material 304.

Returning to FIG. 3, two S/D regions 312-1 and 312-2 (together referred to as “S/D regions 312”) are situated on either side of the recess 330, along the top of the channel material 304. Two S/D contact electrodes 310-1 and 310-2 (together referred to as “contact electrodes 310” or “S/D contact electrodes 310”), formed of one or more electrically conductive materials, may be used for providing electrical connectivity to the S/D regions 312-1 and 312-2, respectively. FIG. 6 illustrates a second cross-sectional view in the y-z plane of the example coordinate system shown in FIG. 3, with the cross section taken along the second S/D region 312-2 and S/D contact electrode 310-2 (e.g., along the plane shown in FIG. 4 as a plane CC′).

The S/D regions 312 may generally be formed using either an implantation/diffusion process or an etching/deposition process. In the former process, dopants such as boron, aluminum, antimony, phosphorous, or arsenic may be ion-implanted into the channel material to form the source and drain regions. An annealing process that activates the dopants and causes them to diffuse further into the channel material 304 typically follows the ion implantation process. In the latter process, the channel material 304 may first be etched to form recesses at the locations of the source and drain regions. An epitaxial deposition process may then be carried out to fill the recesses with material that is used to fabricate the source and drain regions. In some implementations, the S/D regions 312 may be fabricated using a silicon alloy such as silicon germanium or silicon carbide. In some implementations, the epitaxially deposited silicon alloy may be doped in situ with dopants such as boron, arsenic, or phosphorous. In further embodiments, the S/D regions 312 may be formed using one or more alternate semiconductor materials such as germanium or a group III-V material or alloy. And in further embodiments, one or more layers of metal and/or metal alloys may be used to form the S/D regions 312.

In various embodiments, one or more layers of metal and/or metal alloys may be used to form the S/D contact electrodes 310. For example, the electrically conductive materials of the S/D contact electrodes 310 may include one or more metals or metal alloys, with materials such as copper, ruthenium, palladium, platinum, cobalt, nickel, hafnium, zirconium, titanium, tantalum, and aluminum, tantalum nitride, tungsten, doped silicon, doped germanium, or alloys and mixtures of any of these. In some embodiments, the S/D contact electrodes 310 may include one or more electrically conductive alloys, oxides, or carbides of one or more metals. In some embodiments, the S/D contact electrodes 310 may include a doped semiconductor, such as silicon or another semiconductor doped with an N-type dopant or a P-type dopant. Metals may provide higher conductivity, while doped semiconductors may be easier to pattern during fabrication. Although FIG. 3 illustrates the first and second S/D contact electrodes 310 with a single pattern, suggesting that the material composition of the first and second S/D contact electrodes 310 is the same, this may not be the case in some other embodiments of the transistor 300. Thus, in some embodiments, the material composition of the first S/D contact electrode 310-1 may be different from the material composition of the second S/D contact electrode 310-2.

As shown in FIG. 4, the S/D regions 312 are located in one layer 410 of the device, above a second layer 412 of the device that includes the portion 504 of the gate stack extending over the portion 406 of the channel material.

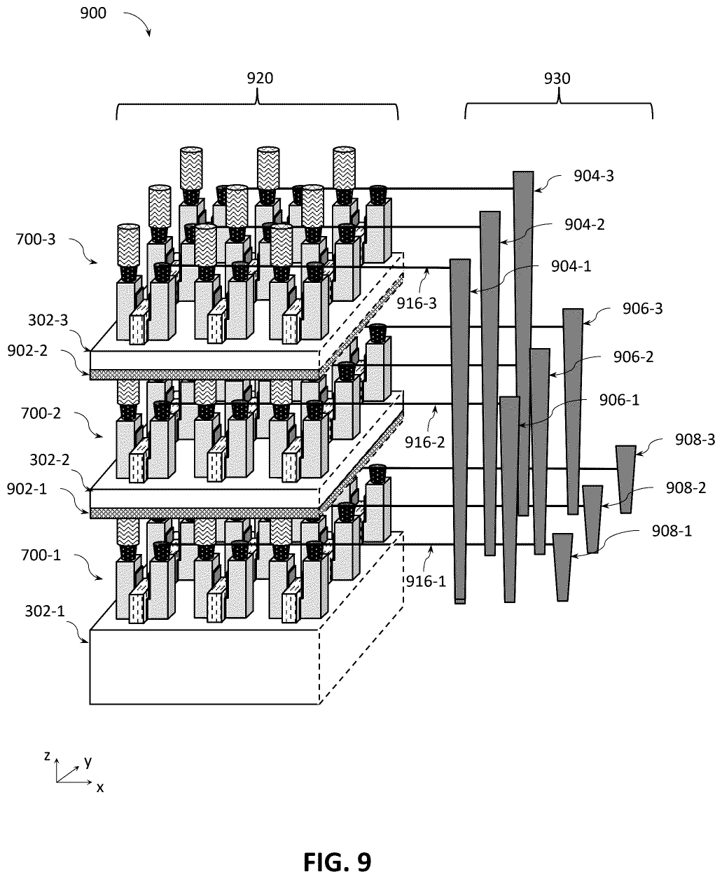

Both layers 410 and 412 are over the support structure 302, and the second layer 412 is situated between the support structure 302 and the first layer 410. In an alternate embodiment, one of the S/D regions may be formed on the back-side, and coupled to a back-side contact. An example of such an embodiment is shown in FIG. 9.

FIGS. 3 and 4 illustrate two distances 340 and 342, where the first distance 340 is a distance from the first S/D region 312-1 and the support structure 302, and the second distance 342 is a distance from the portion of the gate stack situated over the channel material 304 (i.e., the portion 504 of the gate stack) to the support structure 302. The second distance 342 is smaller than the first distance 340, i.e., the distance from the support structure 302 to the portion of the gate stack over the channel material is smaller than the distance from the support structure 302 to the first S/D region 312-1. In this example, with two front-side contacts, the distance from the second S/D region 312-2 to the support structure 302 is the same as the first distance 340. The first distance 340 may have a length between about 20 nanometers to 400 nanometers, including all values and ranges therein, e.g., between about 40 nanometers and 60 nanometers. The second distance 342 may have a length between about 3 nanometers to 100 nanometers, including all values and ranges therein, e.g., between about 3 nanometers and 10 nanometers.

FIG. 4 further illustrates two example paths 420 and 422 between the S/D regions 312-1 and 312-2. The paths 420 and 422 are example current pathways between the S/D regions 312. The path 420 may represent a typical path, extending down from the first S/D region, around the recess 330, and up to the second S/D region 312-2. The path 422 represents a shortest path between the two S/D regions 312, extending from the first S/D region 312-1 down the first sidewall 402-1, across the base 404, up the second sidewall 402-2, and to the second S/D region 312-2. The direction of current may be the opposite of the direction shown in FIG. 4, i.e., current may alternatively travel from the second S/D region 312-2 to the first S/D region 312-1.

As illustrated in FIG. 4, the paths 420 and 422, and in particular, the shortest path 422, is not a straight line. Instead, the shortest path 422 has a “U” shape that extends around the recess 330. This is in contrast to the shortest path of a conventional FinFET, which is a straight line directly under the gate oxide.

The arrangement shown in FIG. 3 (and other figures of the present disclosure) is intended to show relative arrangements of some of the components therein, and that the arrangement with the transistor 300, or portions thereof, may include other components that are not illustrated. For example, although not specifically illustrated in FIG. 3, a dielectric spacer may be provided between one or both of the S/D contact electrodes 310 and the gate electrode 308 in order to provide additional electrical isolation between the source, gate, drain electrodes. In another example, although not specifically illustrated in FIG. 3, at least portions of the transistor 300 may be surrounded in an insulator material, such as any suitable ILD material. In some embodiments, such an insulator material may be a high-k dielectric including elements such as hafnium, silicon, oxygen, titanium, tantalum, lanthanum, aluminum, zirconium, barium, strontium, yttrium, lead, scandium, niobium, and zinc. Examples of high-k materials that may be used for this purpose may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In other embodiments, the insulator material surrounding portions of the transistor 300 may be a low-k dielectric material. Some examples of low-k dielectric materials include, but are not limited to, silicon dioxide, carbon-doped oxide, silicon nitride, organic polymers such as perfluorocyclobutane or polytetrafluoroethylene, fused silica glass (FSG), and organosilicates such as silsesquioxane, siloxane, or organosilicate glass.

### Example Single-Layer Memory Array

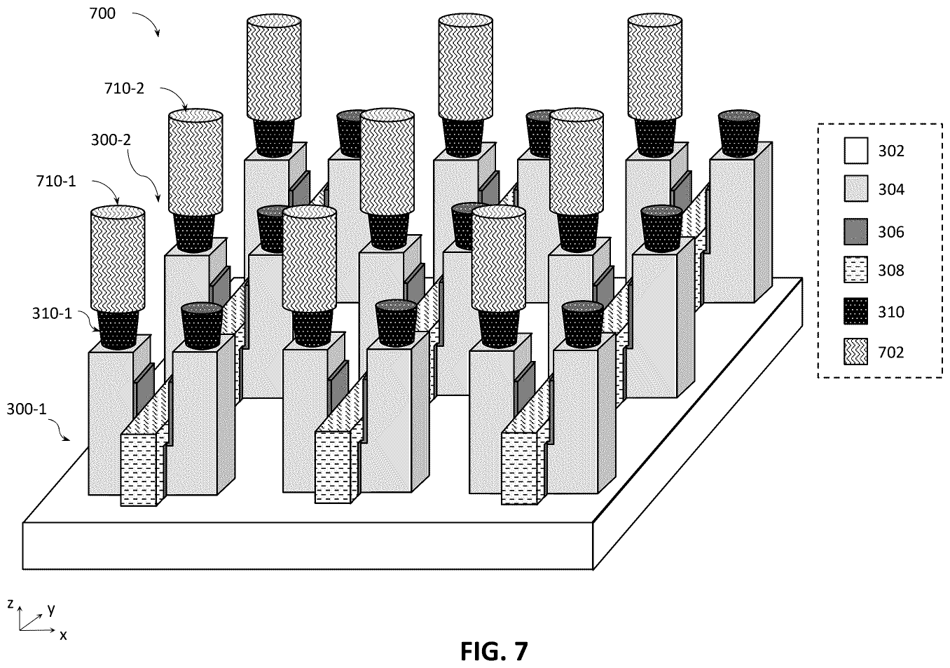

FIG. 7 is a perspective view of an example array 700 of 1T-1C memory cells that include three-dimensional transistors with recessed gates, according to some embodiments of the present disclosure. The array 700 is an example implementation of the array 210 shown in FIG. 2, with nine example 1T-1C memory cells arranged in rows and columns (here, three rows and three columns). While the array 700 shown in FIG. 7 has nine memory cells, in other embodiments, the array 700 may, and typically would, include many more memory cells. Each of the memory cells includes the transistor 300 shown in FIG. 3, and a capacitor 710 represented in the legend with the pattern 702. The legend further shows the materials 302-310 shown in FIG. 3; in this illustration, the S/D regions 312 are not specifically shown.

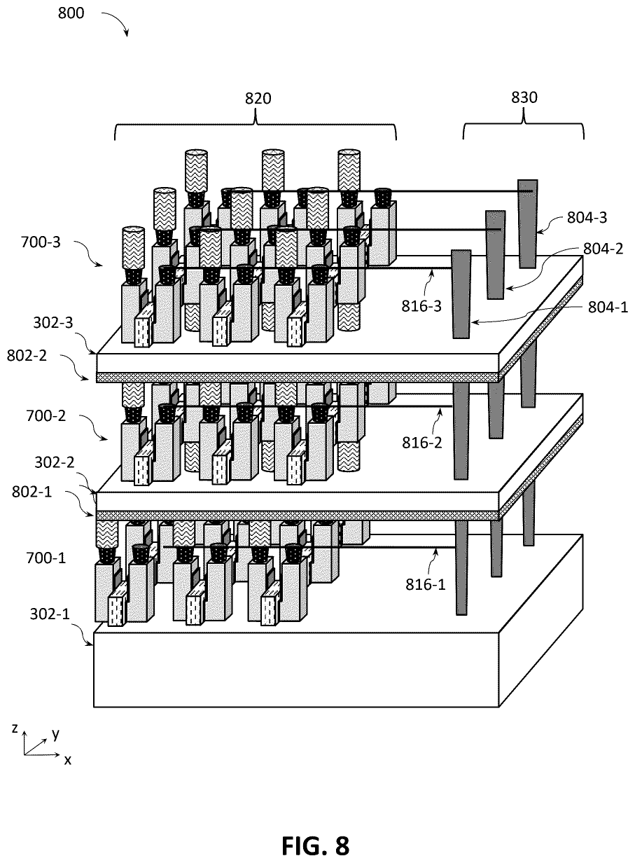

For example, a first memory cell includes a first transistor 300-1 coupled to a first capacitor 710-1, and a second memory cell includes a second transistor 300-2 coupled to a second capacitor 710-2. The capacitors 710 are each coupled to the first contact electrode of the corresponding transistor; e.g., the capacitor 710-1 is coupled to the first contact electrode 310-1 of the first transistor 300-1. The capacitors 710 are further coupled to a PL, as shown in FIG. 2; the PL is omitted from FIG. 7. The second contact electrode of each transistor 300 is coupled to a BL, as shown in FIG. 2; the BL is also omitted from FIG. 7, but example BLs are shown in FIGS. 8 and 9. The BLs connect transistors along the x-direction in the orientation of FIG. 7. In alternate embodiments, the capacitors 710 may be coupled to the second contact electrodes 310-2 and the BLs coupled to the first contact electrodes 310-1.

The gate electrodes 308 extend in the y-direction in the orientation of FIG. 7, forming a WL. For example, the gate electrode 308 of the first transistor 300-1 extends in the y-direction to the gate electrode 308 of the second transistor 300-2. Each WL is also coupled to one or more WL contacts (not shown) to apply signals to the WL.

### Example Vertically Stacked and Bonded Memory Arrays

FIG. 8 is a perspective view of an example vertically stacked and bonded memory array, according to some embodiments of the present disclosure. The memory array 800 includes three layers of the memory array 700 shown in FIG. 7, where the memory layers 700 are vertically stacked and bonded together, forming a three-dimensional memory array. Each layer 700 includes a support structure, an array of memory cells, and an interconnect region. Within each layer, the memory cells are in the memory region 820 and a set of vias 804 are in an interconnect region 830. For example, the first layer 700-1 includes a first array of the memory cells shown in FIG. 7 over a first support structure 302-1, the second layer 700-2 includes a second array of the memory cells over a second support structure 302-2, and the third layer 700-3 includes a third array of the memory cells over a third support structure 302-3. The memory array 800 may include more or fewer memory layers, including two memory layers 700, or four or more memory layers 700.

Each memory layer 700 includes a set of BLs 816 coupled to the memory cells, and in particular, coupled to S/D contacts of the transistors. As described with respect to FIG. 2, one of the S/D terminals of each transistor is coupled to a BL 816, and the other one of the S/D terminals of the transistor is coupled to a capacitor. In the orientation shown in FIG. 8, the left S/D contact is coupled to a capacitor, and the right S/D contact is coupled to the BL 816. For example, the right S/D contacts of each of the front-most memory cells (in the y-direction and as depicted in FIG. 8) in the first layer 700-1 are each connected to a first BL 816-1, the right S/D contacts of each of the front-most memory cells in the second layer 700-2 are each connected to a second BL 816-2, and the right S/D contacts of each of the front-most memory cells in the third layer 700-3 are each connected to a third BL 816-3.

While the BLs 816 are depicted as extending below the capacitors and above the left S/D contacts, the BLs 816 may be electrically isolated from the capacitors and left S/D contacts, e.g., using a dielectric material, or by routing the BLs 816 around the capacitors and left S/D contacts. As another example, rather than aligning the transistors so that their sidewalls extend in the x-and y-directions as shown in FIG. 8, the transistors may be fabricated at an angle, so that the left S/D contact is slightly in front of the right S/D contact in the y-direction, or the left S/D contact is slightly behind the right S/D contact in the y-direction. If the transistors are angled, and the BLs 816 extend along the x-direction, the BLs 816 contact the right S/D contacts while skipping the left B/L contacts, which are offset from the BLs 816. As still another example, the transistors may have the same arrangement shown in FIG. 8, and S/D contacts themselves are staggered, so that the left S/D contact is further towards the front in the y-direction and the right S/D contact is further towards the back in the y-direction, or vice versa. If the S/D contacts are offset, and the BLs 816 extend along the x-direction, the BLs 816 contact the right S/D contacts while skipping the left B/L contacts, which are offset from the BLs 816.

In some embodiments, each memory layer 700 is separately fabricated on a respective support structure 302, which may be similar to the support structure 110. For example, the memory layers 700-1, 700-2, and 700-3 may be fabricated on separate wafers, or on different dies of the same wafer. The BLs 816 may be deposited during the fabrication process, e.g., between processing the transistors and the capacitors. Other various features not shown in FIG. 8 may also be processed during this stage, e.g., WLs and PLs, ILD layers, etc. After each memory layer 700 is formed on its respective support structure 302, the support structure is grinded, which significantly thins the support structure 302 and the overall memory layer 700. In some embodiments, the support structure 302 of the lower-most layer (in this case, the support structure 302-1) is not grinded, or is grinded a lesser amount, than the support structures of upper layers (in this case, the support structures 302-2 and 302-3), because the support structure 302-1 of the lower-most memory layer acts as a support structure for the full memory array 800. For example, the support structures 302-1, 302-2, and 302-3 may each have an initial thickness (a dimension measured in the direction of the z-axis of the reference coordinate system) between about 1 micron and 100 microns, which provides a suitably robust structure for processing the memory layers 700-1, 700-2, and 700-3. After the second and third memory layers 700-2 and 700-3 are processed, their front-sides may be attached to a respective carrier structure (e.g., a second support structure), while the support structures 302-2 and 302-3 on the back-sides are grinded to a thickness less than about 5 microns, including any range therein, e.g., between 1 nanometers and 50 nanometers. In some embodiments, the support structures 302-2 and/or 302-3 are completely removed, i.e., to a thickness of 0 nanometers. Thinning the support structures 302 for the upper memory layers enables the memory layers 700 to be vertically stacked and bonded, with vias 804 extending through the support structures to access the memory layers 700. In addition, thinner support structures 302-2 and 302-3 enables a tighter pitch between vias (i.e., a smaller distance between the first via 804-1 and the second via 804-2).

The memory array 800 includes bonding interfaces between the layers 700. For example, a first bonding interface 802-1 couples the support structure 302-2 of the second memory layer 700-2 to the first memory layer 700-1, and a second bonding interface 802-2 couples the support structure 302-3 of the third memory layer 700-3 to the second memory layer 700-2. The bonding interfaces 802 include a bonding material to bond adjacent memory layers 700 together. The bonding interfaces 802 may be similar to the bonding interface 140 described with respect to FIG. 1.

In some alternate embodiments, e.g., embodiments where TFTs are used, the upper memory layers 700-2 and 700-3 may be processed over the first memory layer 700-1, rather than processed separately and bonded. In such embodiments, a support structure 302-2 and 302-3 may be present for the upper layers, e.g., after the first memory layer 700-1 is processed, the support structure 302-2 is deposited over the top of the first memory layer 700-1, and the second memory layer 700-2 is processed over the support structure 302. In such embodiments, the support structures 302 of the upper memory layers (e.g., the support structures 302-2 and 302-3) may have a thickness between about 5 nanometers to 100 nanometers.

Each BL 816 is coupled to a via 804 that extends through the memory layers 700. The vias 804 are in the interconnect region 830, and the BLs 816 extend between the memory region 820 and the interconnect region 830. In the example shown in FIG. 8, the first BL 816-1, second BL 816-2, and third BL 816-3 are each coupled to a first via 804-1. BLs for different columns of memory cells are coupled to different vias; for example, the second columns of memory cells in each of the layers 700-1, 700-2, and 700-3 behind the front-most columns are coupled to a second via 804-2; the third columns of memory cells are coupled to a third via 804-3. The vias 804 extend through the memory layers 700, including their support structures 302, and the bonding interfaces 802. For example, the via 804-1 extends from the memory layer 700-3 through the support structure 302-3, bonding interface 802-2, support structure 302-2, bonding interface 802-1, and to, into, or through the support structure 302-1. The vias 804 may extend through additional layers or materials not shown, e.g., an ILD layer between the support structure 302-1 and bonding interface 802-1, and an ILD layer between the support structure 302-1 and bonding interface 802-2. The vias 804 may extend higher and/or lower than depicted, e.g., partially into the lowermost support structure 302-1, or through the support structure 302-1 and into a layer below (e.g., to the compute logic layer 120).

In some embodiments, portions of the vias 804 extending through each memory layer 700 are processed before the memory layers 700 are stacked. For example, the memory layer 700-1 includes a first portion of the via 804-1, the memory layer 700-2 includes a second portion of the via 804-1, and the memory layer 700-3 includes a third portion of the via 804-1. When the memory layers 700-1, 700-2, and 700-3 are bonded together, the respective portions of the via 804-1 are aligned and connected, forming the via 804-1 extending through the three memory layers 700-1, 700-2, and 700-3. In other embodiments, the vias 804 are formed through the full memory array 800 after the memory layers 700 are fabricated and bonded.

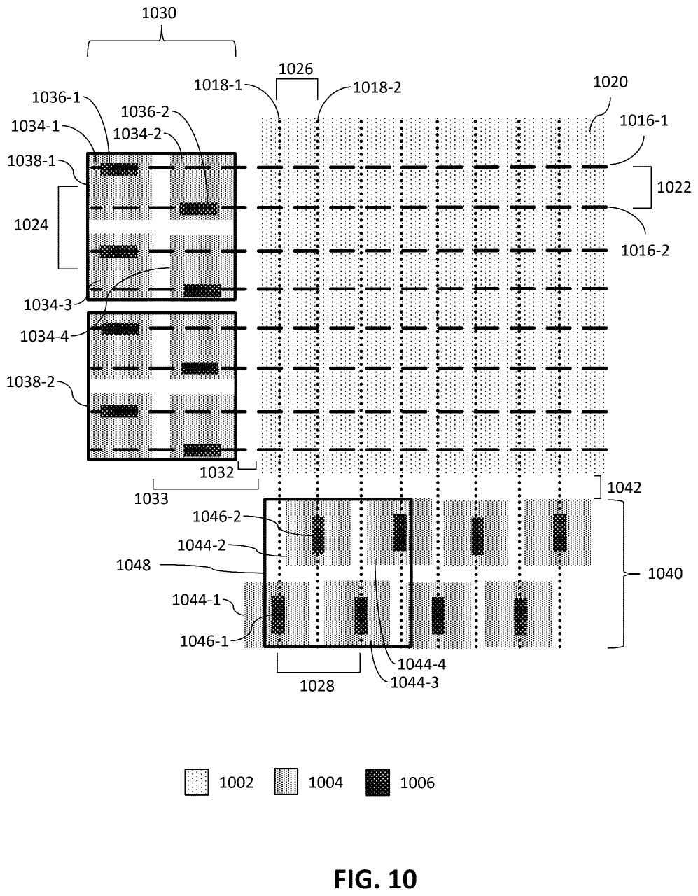

In the example of FIG. 8, the vias 804-1, 804-2, and 804-3 extend along a line in the y-direction, and each of the vias 804 is a same distance from the memory region 820. In this example, the pitch between the BLs 816 is the same as the pitch between the vias 804. As discussed above, as memory arrays become more dense and the pitch between BLs 816 decrease, it may not be possible to form the vias 804 with the same narrow pitch as the pitch between the BLs 816, particularly for tall vias that extend through multiple layers of memory. For example, in the example of FIG. 8, the vias 804 extend through three memory layers, and also across two bonding interfaces 802- and 802-2 and two support structures 302-2 and 302-3. In other examples, the vias may be shorter (e.g., extending through one memory layer and one support structure), but it may be challenging to connect and align the vias in a bonding layer at the tolerance needed to achieve the narrow BL pitch. Therefore, in some embodiments disclosed herein, the vias 804 may be staggered, so that a portion of the vias are at a farther distance away from the memory region 820 than another portion of the vias. Several example via arrangements are illustrated in FIGS. 10-15, described below.

FIG. 9 is a perspective view of an example vertically stacked and bonded memory array with a different via configuration, according to some embodiments of the present disclosure. The memory array 900 includes three layers of the memory array 700 shown in FIG. 7, where the memory layers 700 are vertically stacked and bonded together, forming a three-dimensional memory array. As in FIG. 8, each layer 700 includes a support structure and an array of memory cells, and the arrangement of the memory layers 700 in FIG. 9 is similar to the arrangement of the memory layers 700 described above with respect to FIG. 8. Within each layer, the memory cells are in the memory region 920 and a set of vias are in an interconnect region 930. For example, within the memory region 920, the layer 700-1 includes a first array of the memory cells shown in FIG. 7 over a first support structure 302-1, the layer 700-2 includes a second array of the memory cells over a second support structure 302-2, and the layer 700-3 includes a third array of the memory cells over a third support structure 302-3. Each memory layer 700 includes a set of BLs 916, e.g., memory layer 700-1 includes BL 916-1, memory layer 700-2 includes BL 916-2, and memory layer 700-3 includes BL 916-3, which are similar to the BLs 816 in FIG. 8. The BLs 916 extend between the memory region 920 and the interconnect region 930. The memory layers 700 are bonded together at bonding interfaces 902-1 and 902-2, which are similar to the bonding interfaces 802 described with respect to FIG. 8.

In the arrangement of FIG. 8, each via 804 was coupled to a BL on each of the memory layers 700, e.g., via 804-1 was coupled to BLs 816-1, 816-2, and 816-3. In the arrangement shown in FIG. 9, each respective memory layer 700 is coupled to a different set of vias 904. For example, the first memory layer 700-1 has three BLs, each coupled to one of a first set of vias 908 (e.g., BL 916-1 is coupled to the via 908-1); the second memory layer 700-2 has three BLs, each coupled to one of a second set of vias 906 (e.g., BL 916-2 is coupled to the via 906-1); and the third memory layer 700-3 has three BLs, each coupled to one of a third set of vias 904 (e.g., BL 916-3 is coupled to the via 904-1). In this example, the portions of the support structures 302 and bonding interfaces 902 are cut away in the region of the vias 904, 906, and 908 to better show the arrangement of the vias, but the support structures 302 and bonding interfaces 902 may extend through the region of the vias, as shown in FIG. 8.

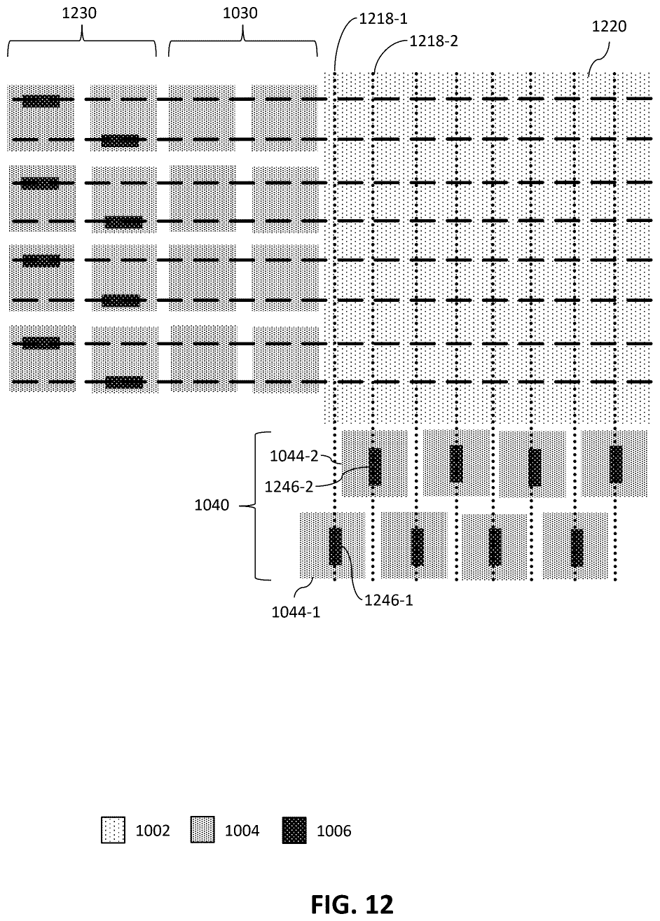

Some BLs 916 are depicted as extending near or through certain vias to which they are not coupled, e.g., the BL 916-1, coupled to the via 908-1, is depicted as extending through the vias 904-1 and 906-1, and the BL 916-2, coupled to the via 906-1 is depicted as extending through the via 904-1. The BLs 916 may be electrically isolated from the vias to which they are not coupled, e.g., by using a dielectric material, or by routing the BLs 916 around the vias to which they are not coupled. In other embodiments, the vias 904-908 may be arranged differently than shown in FIG. 9; for example, the vias 908 coupled to the lowest memory layer 700-1 may be positioned nearest to the memory cells, and the vias 904 coupled to the highest memory layer 700-3 may be positioned farthest from the memory cells; such an example is shown in FIG. 12.

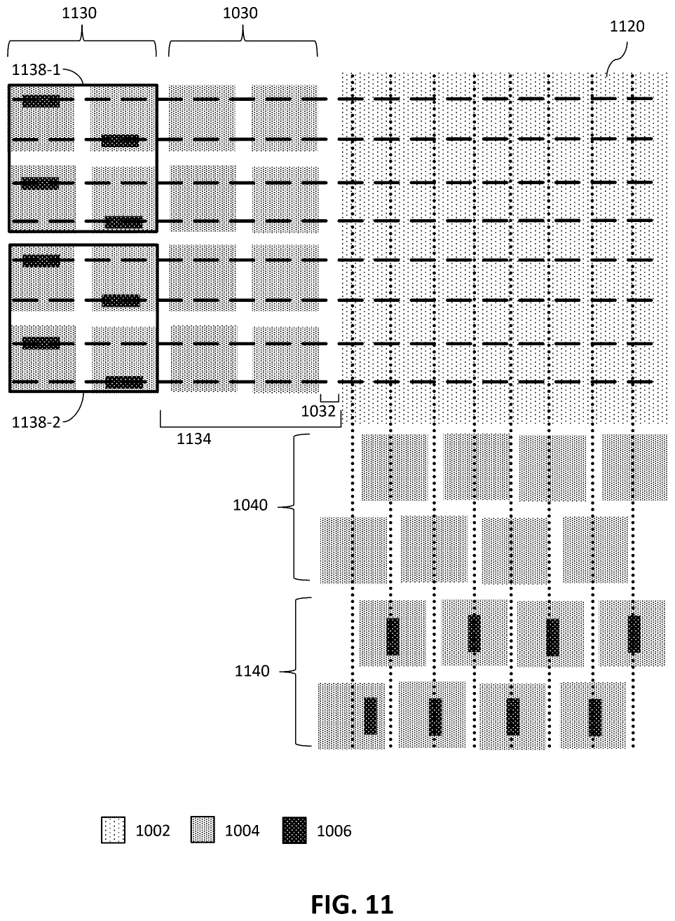

As described with respect to FIG. 8, within a single layer 700, the vias are arranged along a line in the y-direction. For example, the vias 904-1, 904-2, and 904-3 extend along a line in the y-direction, and each of the vias 904 is a same distance from the memory region 920. Likewise, the vias 906-1, 906-2, and 906-3 extend along another line in the y-direction, and each of the vias 906 is a same distance from the memory region 920. Thus, in this example, as in FIG. 8, the pitch between the BLs 916 is the same as the pitch between the vias 904, 906, and 908. This may lead to the challenges described above. Therefore, in some embodiments disclosed herein, the vias 904, 906, and/or 908 may be staggered, so that, within a given set of vias, a portion of the vias are at a farther distance away from the memory region 820 than another portion of the vias. Several example via arrangements are illustrated in FIGS. 10-15, described below. Each layer 700 may have a different interconnect region, where the interconnect regions are at different distances from the memory region 920, e.g., as described with respect to FIGS. 11, 12, and 15.

While the memory arrays 800 and 900 are illustrated as comprising three-dimensional transistors with a recessed gate, embodiments of the present disclosure are not limited to only this design and include memory arrays comprising transistors of various other architectures, or a mixture of different architectures. For example, bottom-gated transistors, top-gated transistors, FinFETs, nanowire transistors, and planar transistors, and memory arrays containing such transistor architectures, are within the scope of the present disclosure.

While the memory arrays 800 and 900 show the BL arrangements and vias coupled to the BLs, each memory cell may be similarly coupled to vias for controlling its WL and/or PL. For example, the WLs of rows of memory cells may extend in the y-direction in the orientation of FIGS. 8 and 9, and the WLs may be connected to a set of vias similar to the vias 804 or the vias 904-908.

### Example Interconnect Arrangements

FIG. 10 is a top plan view of a first memory layer including a memory region and interconnect regions coupled to BLs and WLs of the memory region, according to some embodiments of the present disclosure. FIG. 10 includes a memory region 1020 that includes a memory array 1002. The memory array 1002 may represent the memory cells described above, e.g., the memory cells 200, or the memory array 700. As illustrated in FIGS. 2, 8, and 9, BLs and WLs are coupled to the memory array 1002. In FIG. 10, a series of BLs 1016, including a first BL 1016-1 and a second BL 1016-2, extend across the memory array 1002. The BLs 1016 may each be coupled to a column of memory cells, as described above. FIG. 10 further includes a series of WLs 1018, including a first WL 1018-1 and a second WL 1018-2. The WLs 1018 extend across the memory array 1002, and the WLs 1018 may each be coupled to a row of memory cells, as described above. In this example, the WLs 1018 extend in a perpendicular direction to the BLs 1016.

The BLs 1016 extend from the memory array 1002 in the memory region 1020 to a set of vias 1034 in an interconnect region 1030. The interconnect region 1030 includes a set of vias 1034, e.g., the vias 1034-1, 1034-2, 1034-3, and 1034-4, which are arranged in a group 1038-1. A similar group 1038-2 of vias 1034 is below the first group 1038-1. Additional groups may be connected to additional columns of BLs 1016, e.g., additional BLs 1016 above the BL 1016-1 in the orientation of FIG. 10. The interconnect region 1030 is a distance 1032 away from the memory region 1020.

The arrangement of the memory region 1020 and interconnect region 1030 may be similar to the arrangement of the memory region 820 and interconnect region 830, or the memory region 920 and interconnect region 930, shown in FIGS. 8 and 9. However, unlike in FIGS. 8 and 9, the vias 1034 are not arranged in a single line, but rather are staggered or stacked, with some vias farther from the memory region 1020 than others. For example, the via 1034-1 is a distance 1033 away from the memory region 1020, and the via 1034-2 is the distance 1032 away from the memory region 1020, where the distance 1033 is greater than the distance 1032. In this example, the via 1034-2 is arranged between the memory array 1002 and the 1034-1.

FIG. 10 further illustrates connection areas 1006 between BLs 1016 and vias 1034. For example, the BL 1016-1 is coupled (e.g., physically and electrically connected) to the via 1034-1 at the connection area 1036-1, and the BL 1016-2 is coupled to the via 1034-2 at the connection area 1036-2. The BL 1016-1 is not coupled to the via 1034-2; for example, the BL 1016-1 may be surrounded by an insulator in the area of the via 1034-2, so that the BL 1016-1 is not electrically coupled to the via 1034-2.

The BLs 1016 are arranged at a first pitch 1022. The vias 1034 are arranged at a second pitch 1024. The second pitch 1024 is greater than the first pitch 1022. Because of the relatively large pitch 1024 of the vias 1034, the vias 1034 cannot be arranged along a single line at the relatively small pitch 1022 of the BLs 1016. Instead, the vias 1034 are arranged with a portion of the vias 1034 (e.g., the vias 1034-1 and 1034-3) set behind another portion of the vias 1034 (e.g., the vias 1034-2 and 1034-4). In this example, the vias 1034-1 and 1034-3 are directly behind the vias 1034-2 and 1034-4, relative to the memory region 1020. In other embodiments, the positions of vias within different rows may be staggered, e.g., as illustrated in the interconnect region 1040, described below.

As noted above, the interconnect region 1030 includes two via groups 1038-1 and 1038-2. Each group 1038 may have an area that is the number of vias in the group (here, 4) times the square of the second pitch 1024. For example, if the second pitch 1024 is 50 nanometers (nm), the area of the group 1038-1 is 4*(50 nm)²=10000 nm². Each group 1038 may have the same area, e.g., the area of the group 1038-2 is also 10000 nm². More generally, the area of the interconnect region 1030 may be the total number of BLs multiplied by the square of the second pitch 1024, e.g., if the interconnect region 1030 includes 32 BLs, the area of the interconnect region 1030 is 32*(50 nm)²=80000 nm². In some cases, this formula may represent a minimum area for an interconnect region; in some cases, the vias 1034 may be arranged greater spacing in certain areas or in certain directions, e.g., to reduce capacitance in an interconnect region.

The WLs 1018 extend from the memory array 1002 in the memory region 1020 to a set of vias 1044 in an interconnect region 1040. The interconnect region 1040 is a distance 1042 from the memory region 1020. The interconnect region 1040 includes a set of vias 1044, e.g., the vias 1044-1 and 1044-2. The vias 1044 are similar to the vias 1034. Additional vias 1044 may be connected to additional rows of WLs 1018, e.g., additional WLs 1018 to the right of the WLs shown in FIG. 10.

In this example, while the vias 1034 are stacked in two rows (e.g., the row with the vias 1034-1 and 1034-3, and the row with the vias 1034-2 and 1034-4), the vias 1044 have a staggered arrangement, e.g., with the via 1044-2 spaced, along the horizontal direction, between the vias 1044-1 and 1044-3. As with the interconnect region 1030, in the interconnect region 1040, some vias 1044 are a greater distance away from the memory region 1020 than other vias 1044; for example, the via 1044-1 is a greater distance away from the memory region 1020 than the via 1044-2. FIG. 10 illustrates connection areas 1006 between WLs 1018 and vias 1044. For example, the WL 1018-1 is coupled (e.g., physically and electrically connected) to the via 1044-1 at the connection area 1046-1, and the WL 1018-2 is coupled to the via 1044-2 at the connection area 1046-2. In this example, the WLs to the farther vias (e.g., the vias 1044-1 and 1044-3) do not pass through the areas of the closer vias (e.g., the vias 1044-2 and 1044-4).

The WLs 1018 are arranged at a third pitch 1026. The vias 1044 are arranged at a fourth pitch 1028. In this example, the first pitch 1022 is similar to the third pitch 1026, but the first pitch 1022 and third pitch 1026 may be different. Likewise, the second pitch 1024 is similar to the fourth pitch 1028, but these pitches may be different. The fourth pitch 1028 is greater than the third pitch 1026. Because of the relatively large pitch 1028 of the vias 1044, the vias 1044 cannot be arranged along a single line at the relatively small pitch 1026 of the WLs 1018. Instead, as with the vias 1034, the vias 1044 are arranged with a portion of the vias 1044 (e.g., the vias 1044-1 and 1044-3) set behind another portion of the vias 1044 (e.g., the vias 1044-2 and 1044-4). In this example, the vias in the two rows are staggered, as described above.

FIG. 10 illustrates a via group 1048. Because the vias have a staggered arrangement, the area of the vias 1044-1, 1044-2, 1044-3, and 1044-4 may be approximated by the bounds of the via group 1048. The area of the via group 1048 may be calculated based on the number of vias in the group and the pitch 1028, using the formula described above with respect to the vias 1034.

FIG. 11 is a top plan view of a second memory layer including a second memory region and second interconnect regions coupled to BLs and WLs of the second memory region, according to some embodiments of the present disclosure. FIG. 11 includes a memory region 1120 that may include a second memory array 1002. The memory region 1120 may be in a different memory layer from the memory region 1020 shown in FIG. 10. For example, FIG. 10 may represent a plan view of WLs, BLs, and interconnect regions of the first memory layer 130, while FIG. 11 represents a plan view of WLs, BLs, and interconnect regions of the second memory layer 150. As in FIG. 10, a series of BLs and a series of WLs extend across the memory array 1002.

The BLs extend from the memory region 1120 a set of vias in an interconnect region 1130. The interconnect region 1130 is arranged to the left side of the interconnect region 1030. The interconnect region 1130 is a greater distance from the memory region 1120 than the interconnect region 1030; here, the interconnect region 1130 is a distance 1132 from the memory region 1120, and the interconnect region 1030 is the distance 1032 from the memory region 1120, where the distance 1132 is greater than the distance 1032. The interconnect region 1130 includes a set of vias that are similar to the vias 1034; the vias of the interconnect region 1130 are arranged in two groups 1138-1 and 1138-2. Additional groups may be connected to additional columns of BLs, as described with respect to FIG. 10.

The BLs shown in FIG. 11 pass through the interconnect region 1030. In the interconnect region 1030, the BLs may be surrounded by an insulator, so that the BLs coupled to the memory region 1120 are not physically or electrically coupled to the vias 1034 in the interconnect region 1030. Thus, the BLs of the memory region 1120 are separately controlled from the BLs in the memory region 1020 of FIG. 10.

The WLs shown in FIG. 11 extend from the memory region 1120 to a set of vias in an interconnect region 1140. The interconnect region 1140 is arranged below the interconnect region 1040 in the orientation shown. The interconnect region 1140 is a greater distance from the memory region 1120 than the interconnect region 1040, e.g., as described with respect to the BL interconnect regions 1130 and 1030.

The interconnect region 1140 includes a set of vias that are similar to the vias 1044. Additional vias may be connected to additional rows of WLs, as described with respect to FIG. 10. The WLs shown in FIG. 11 pass through the interconnect region 1040. In the interconnect region 1040, the WLs may be surrounded by an insulator, so that the WLs coupled to the memory region 1120 are not physically or electrically coupled to the vias 1044 in the interconnect region 1040. Thus, the WLs of the memory region 1120 are separately controlled from the WLs in the memory region 1020 of FIG. 10.

In an alternate embodiment, vias to WLs and/or BLs may be shared across two or more memory layers. FIG. 12 is a top plan view of an alternate arrangement of the second memory layer, according to some embodiments of the present disclosure. In the example of FIG. 12, the interconnect region 1040 is coupled to the WLs 1218 of the memory region 1220 of a second memory layer, different from the memory layer shown in FIG. 10. For example, FIG. 10 may represent a plan view of WLs, BLs, and interconnect regions of the first memory layer 130, while FIG. 12 represents an alternative plan view of WLs, BLs, and interconnect regions of the second memory layer 150.

The BLs extend from the memory region 1220 a set of vias in an interconnect region 1230. The interconnect region 1230 is similar to the interconnect region 1130 described above. As with the interconnect region 1130, the BLs of the memory region 1220 are separately controlled from the BLs in the memory region 1020 of FIG. 10.

The WLs (e.g., the WLs 1218-1 and 1218-2) shown in FIG. 12 extend from the memory region 1220 to the set of vias in the interconnect region 1040. FIG. 12 shows the same vias 1044 as FIG. 10, but at a different position (e.g., a different height) along the vias 1044. FIG. 12 further illustrates connection areas 1006 between the WLs 1218 of memory region 1220 and the vias 1044. For example, the connection area 1246-1 couples (e.g., physically and electrically connects) the WL 1218-1 to the via 1044-1, and the connection area 1246-2 couples the WL 1218-2 to the via 1044-2. Thus, the WLs 1218 of the memory region 1220 may be jointly controlled with the WLs 1018 in the memory region 1020 of FIG. 10.

In alternate embodiments, the BLs of different layers may be connected via the vias 1034 in a similar manner. In such embodiments, the WLs of different layers may be separately controlled, e.g., as shown in FIG. 11.

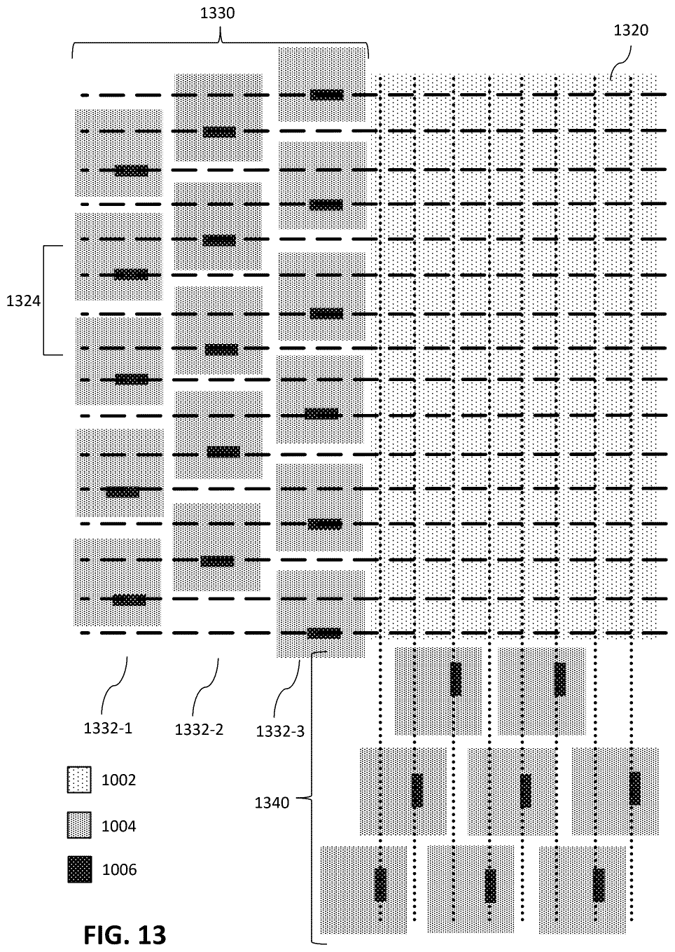

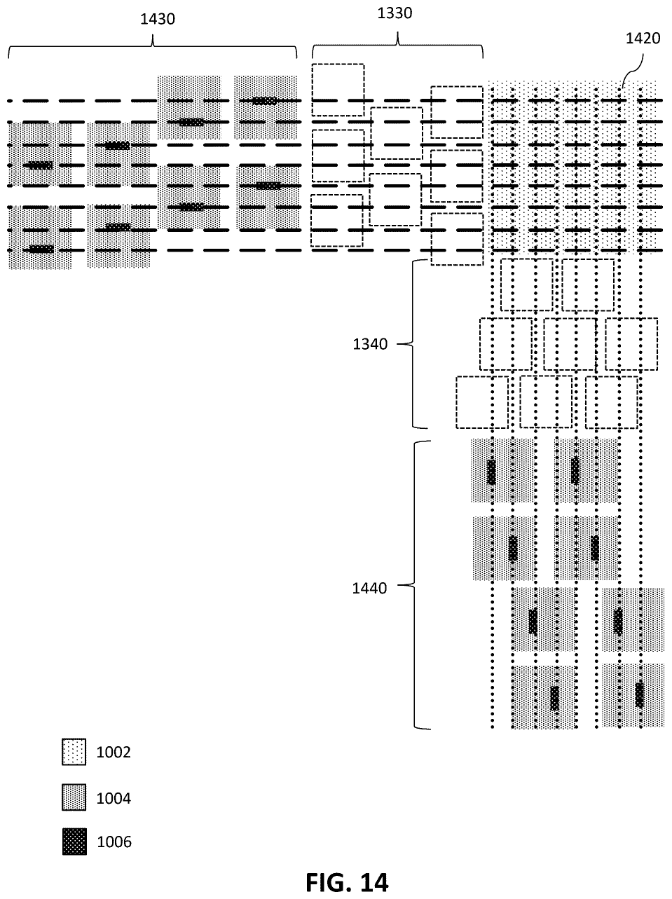

In the examples of FIGS. 10-12, the via pitch was approximately two times the BL and WL pitches. If the via pitch is greater than twice the BL or WL pitch, different via arrangements may be used in the interconnect region. FIGS. 13 and 14 illustrates example via layouts for wider via pitches or, more generally, wider interconnect pitches.

FIG. 13 is a top plan view of a memory layer that includes interconnects arranged at larger pitches, according to some embodiments of the present disclosure. FIG. 13 includes a memory region 1320 that includes a memory array 1002. The memory region 1320 may be similar to the memory region 1020 shown in FIG. 10. As in FIG. 10, a series of BLs and a series of WLs extend across the memory region 1320.

FIG. 13 further includes a first interconnect region 1330 coupled to the BLs and a second interconnect region 1340 coupled to the WLs. While the interconnect regions 1030 and 1040 each had two rows of vias, the interconnect regions 1330 and 1340 each have three rows of vias. For example, the first interconnect region 1330 has vias arranged in three rows 1332-1, 1332-2, and 1332-3, where the vias in row 1332-3 are the shortest distance from the memory region 1320, and the vias in the row 1332-1 are the greatest distance from the memory region 1320. The vias in the interconnect regions 1330 and 1340 have a staggered layout, e.g., the vias in the row 1332-1 are not aligned with vias in the row 1332-2. The vias in FIG. 13 are arranged at a pitch 1324, where the pitch 1324 is more than twice the BL pitch.

In some embodiments, a first memory layer (e.g., the first memory layer 130) has a first via arrangement, and a second layer (e.g., the second memory layer 150) has a second via arrangement different from the first via arrangement. For example, if vias are formed from an upper face of the second memory layer 150 (i.e., the side opposite from the support structure 110), larger vias at wider pitches may be needed to reach the WLs and BLs of the first memory layer 130, while relatively small and narrow vias can reach WLs and BLs of the second memory layer 150.

FIG. 14 illustrates an example memory layer that includes interconnects arranged at larger pitches from FIG. 13. For example, if FIG. 13 illustrates the interconnect regions for the second memory layer 150, FIG. 14 may illustrate interconnect regions for the first memory layer 130. FIG. 14 includes a memory region 1420 that includes a memory array 1002. The memory region 1420 may be similar to the memory region 1020 shown in FIG. 10. As in FIG. 10, a series of BLs and a series of WLs extend across the memory region 1420.

FIG. 14 further includes a first interconnect region 1430 coupled to the BLs and a second interconnect region 1440 coupled to the WLs. In the orientation of FIG. 14, the first interconnect region 1430 is to the left of the area used for the first interconnect region 1330, and the second interconnect region 1440 is below the area used for the interconnect regions 1340. The vias within the first interconnect region 1330 may not extend down to the layer shown in FIG. 14, e.g., to the first memory layer 130, but instead terminate in the layer shown in FIG. 13, e.g., the second memory layer 150. Likewise, the vias within the second interconnect region 1340 may not extend down to the layer shown in FIG. 14, e.g., to the first memory layer 130, but instead terminate in the layer shown in FIG. 13, e.g., the second memory layer 150. Thus, the vias in the first interconnect region 1330 and interconnect regions 1340 are illustrated with dashed boxes, indicating their positions.

While not specifically shown in FIG. 13, the vias in the first interconnect region 1430 and second interconnect region 1440 may extend through the layer illustrated in FIG. 13, e.g., to the left of the first interconnect region 1330 and below the second interconnect region 1340.

The vias in the first interconnect region 1430 and second interconnect region 1440 have still a larger pitch than the vias in the first interconnect region 1330 and interconnect regions 1340. To accommodate the larger pitch, a different arrangement is used, with vias within four different rows, i.e., vias at four different distances from the memory region 1420.

While FIG. 14 illustrates the wider pitch interconnects (e.g., the first interconnect region 1430) as being farther from the memory region compared to the narrower pitch interconnects (e.g., the first interconnect region 1330), in other embodiments, the relative positions of the narrower pitch interconnects and wider pitch interconnects may be reversed.

In FIG. 14, the wider pitch interconnects also were larger than the narrower pitch, e.g., the interconnects in the interconnect regions 1430 and 1440 had larger widths than the interconnects in the interconnect regions 1330 and 1340. In some embodiments, in a given cross-section, interconnects within different interconnect regions may have different sizes but a same pitch. For example, if interconnects are formed from a top face of the second memory layer 150, then in the second memory layer 150, interconnects that connect to WLs and BLs in the second memory layer 150 but do not reach down to the first memory layer 130 may be relatively narrow, while interconnects that continue downward to the first memory layer 130 may be wider. The interconnects that continue to the first memory layer 130 may be narrower in the first memory layer 130 than in the second memory layer 150, because vias tend to taper moving away from the direction from which they are etched. In some embodiments, the vias that reach only to second memory layer 150 may be arranged at the same pitch as the vias that reach to the first memory layer 130, even though a tighter pitch may be possible, e.g., to reduce capacitance within the IC device 100.

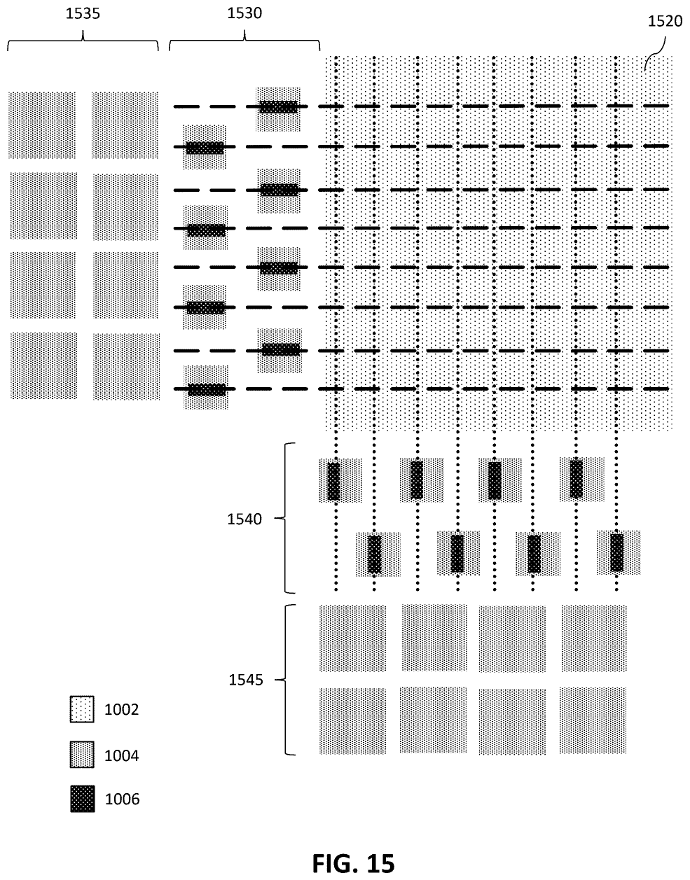

FIG. 15 is a top plan view of interconnect regions with different interconnect sizes in different layers, according to some embodiments of the present disclosure. FIG. 15 includes a memory region 1520 that includes a memory array 1002. The memory region 1520 may be similar to the memory region 1020 shown in FIG. 10. As in FIG. 10, a series of BLs and a series of WLs extend across the memory region 1520.

The WLs are coupled to vias in a first interconnect region 1530, and the BLs are coupled to vias in a second interconnect region 1540. The interconnect regions 1530 and 1540 are similar to other interconnect regions described above. A third interconnect region 1535 is on the opposite side of the first interconnect region 1530 relative to the memory region 1520, and a fourth interconnect region 1545 is on the opposite side of the second interconnect region 1540 relative to the memory region 1520. The third interconnect region 1535 and fourth interconnect region 1545 include vias that may extend to another memory layer, e.g., FIG. 15 may illustrate a cross-section through the second memory layer 150, and the vias in the third interconnect region 1535 and fourth interconnect region 1545 may extend to the first memory layer 130 and be coupled to BLs and WLs within the first memory layer 130.

In this example, the vias in the first interconnect region 1530 and third interconnect region 1535 are arranged at a same pitch. Likewise, the vias in the second interconnect region 1540 and fourth interconnect region 1545 are arranged at a same pitch. However, the vias in the first interconnect region 1530 are narrower than the vias third interconnect region 1535, and the vias in the second interconnect region 1540 are narrower than the vias fourth interconnect region 1545.

### Example Devices

The circuit devices with DRAM layers having the interconnect arrangements disclosed herein may be included in any suitable electronic device. FIGS. 16-19 illustrate various examples of apparatuses that may include the one or more memory layers disclosed herein, which may have been fabricated using the processes disclosed herein.

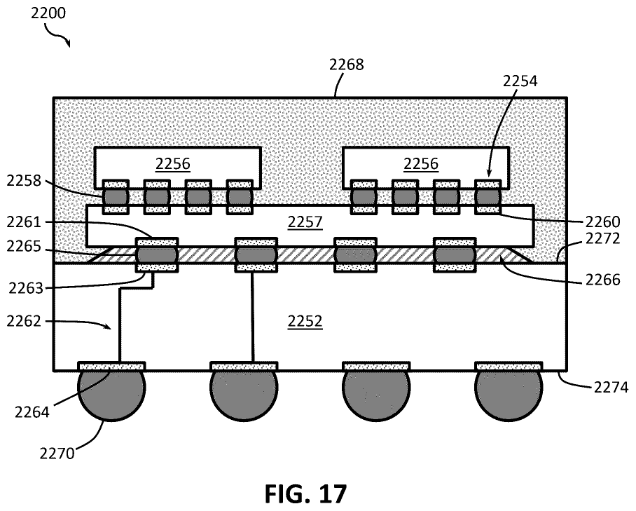

FIG. 16 illustrates top views of a wafer 2100 and dies 2102 that may include one or more DRAM layers having the interconnect arrangements in accordance with any of the embodiments disclosed herein. In some embodiments, the dies 2102 may be included in an IC package, in accordance with any of the embodiments disclosed herein. For example, any of the dies 2102 may serve as any of the dies 2256 in an IC package 2200 shown in FIG. 17. The wafer 2100 may be composed of semiconductor material and may include one or more dies 2102 having IC structures formed on a surface of the wafer 2100. Each of the dies 2102 may be a repeating unit of a semiconductor product that includes any suitable IC (e.g., ICs including one or more DRAM layers with interconnect arrangements as described herein). After the fabrication of the semiconductor product is complete (e.g., after manufacture of any embodiment of the IC device 100 as described herein), the wafer 2100 may undergo a singulation process in which each of the dies 2102 is separated from one another to provide discrete “chips” of the semiconductor product. In particular, devices that include one or more DRAM layers having the interconnect arrangements as disclosed herein may take the form of the wafer 2100 (e.g., not singulated) or the form of the die 2102 (e.g., singulated). The die 2102 may include supporting circuitry to route electrical signals to various memory cells, transistors, capacitors, as well as any other IC components. In some embodiments, the wafer 2100 or the die 2102 may implement or include a memory device (e.g., a hysteretic memory device), a logic device (e.g., an AND, OR, NAND, or NOR gate), or any other suitable circuit element. Multiple ones of these devices may be combined on a single die 2102. For example, a memory array formed by multiple memory devices may be formed on a same die 2102 as a processing device (e.g., the processing device 2402 of FIG. 17) or other logic that is configured to store information in the memory devices or execute instructions stored in the memory array.

FIG. 17 is a side, cross-sectional view of an example IC package 2200 that may include one or more DRAM layers having the interconnect arrangements in accordance with any of the embodiments disclosed herein. In some embodiments, the IC package 2200 may be a system-in-package (SiP).

The package substrate 2252 may be formed of a dielectric material (e.g., a ceramic, a buildup film, an epoxy film having filler particles therein, etc.), and may have conductive pathways extending through the dielectric material between the face 2272 and the face 2274, or between different locations on the face 2272, and/or between different locations on the face 2274.

The package substrate 2252 may include conductive contacts 2263 that are coupled to conductive pathways 2262 through the package substrate 2252, allowing circuitry within the dies 2256 and/or the interposer 2257 to electrically couple to various ones of the conductive contacts 2264 (or to other devices included in the package substrate 2252, not shown).

The IC package 2200 may include an interposer 2257 coupled to the package substrate 2252 via conductive contacts 2261 of the interposer 2257, first-level interconnects 2265, and the conductive contacts 2263 of the package substrate 2252. The first-level interconnects 2265 illustrated in FIG. 17 are solder bumps, but any suitable first-level interconnects 2265 may be used. In some embodiments, no interposer 2257 may be included in the IC package 2200; instead, the dies 2256 may be coupled directly to the conductive contacts 2263 at the face 2272 by first-level interconnects 2265.

The IC package 2200 may include one or more dies 2256 coupled to the interposer 2257 via conductive contacts 2254 of the dies 2256, first-level interconnects 2258, and conductive contacts 2260 of the interposer 2257. The conductive contacts 2260 may be coupled to conductive pathways (not shown) through the interposer 2257, allowing circuitry within the dies 2256 to electrically couple to various ones of the conductive contacts 2261 (or to other devices included in the interposer 2257, not shown). The first-level interconnects 2258 illustrated in FIG. 17 are solder bumps, but any suitable first-level interconnects 2258 may be used. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

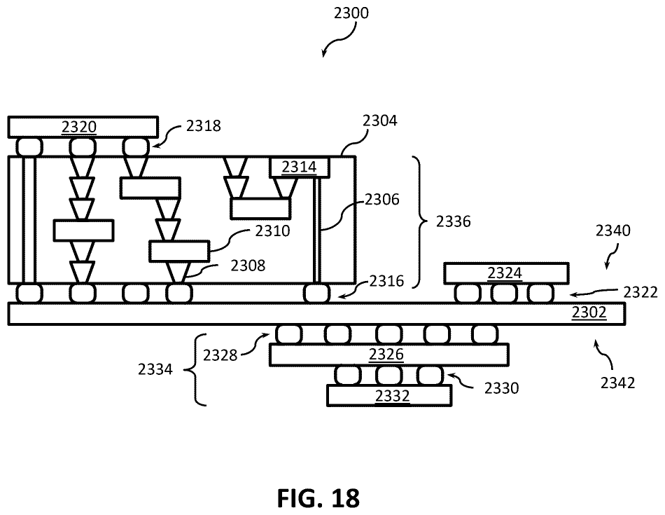

In some embodiments, an underfill material 2266 may be disposed between the package substrate 2252 and the interposer 2257 around the first-level interconnects 2265, and a mold compound 2268 may be disposed around the dies 2256 and the interposer 2257 and in contact with the package substrate 2252. In some embodiments, the underfill material 2266 may be the same as the mold compound 2268. Example materials that may be used for the underfill material 2266 and the mold compound 2268 are epoxy mold materials, as suitable. Second-level interconnects 2270 may be coupled to the conductive contacts 2264. The second-level interconnects 2270 illustrated in FIG. 17 are solder balls (e.g., for a ball grid array arrangement), but any suitable second-level interconnects 22770 may be used (e.g., pins in a pin grid array arrangement or lands in a land grid array arrangement). The second-level interconnects 2270 may be used to couple the IC package 2200 to another component, such as a circuit board (e.g., a motherboard), an interposer, or another IC package, as known in the art and as discussed below with reference to FIG. 18.

The dies 2256 may take the form of any of the embodiments of the die 2102 discussed herein (e.g., may include any of the embodiments of the IC devices with one or more DRAM layers having the interconnect arrangements as described herein). In embodiments in which the IC package 2200 includes multiple dies 2256, the IC package 2200 may be referred to as a multi-chip package (MCP). The dies 2256 may include circuitry to perform any desired functionality. For example, one or more of the dies 2256 may be logic dies (e.g., silicon-based dies), and one or more of the dies 2256 may be memory dies (e.g., high bandwidth memory), including embedded memory dies as described herein. In some embodiments, any of the dies 2256 may include one or more IC devices with one or more DRAM layers having the interconnect arrangements, e.g., as discussed above; in some embodiments, at least some of the dies 2256 may not include any DRAM layers as described herein.

The IC package 2200 illustrated in FIG. 17 may be a flip chip package, although other package architectures may be used. For example, the IC package 2200 may be a ball grid array (BGA) package, such as an embedded wafer-level ball grid array (eWLB) package. In another example, the IC package 2200 may be a wafer-level chip scale package (WLCSP) or a panel fan-out (FO) package. Although two dies 2256 are illustrated in the IC package 2200 of FIG. 17, an IC package 2200 may include any desired number of the dies 2256. An IC package 2200 may include additional passive components, such as surface-mount resistors, capacitors, and inductors disposed on the first face 2272 or the second face 2274 of the package substrate 2252, or on either face of the interposer 2257. More generally, an IC package 2200 may include any other active or passive components known in the art.

FIG. 18 is a cross-sectional side view of an IC device assembly 2300 that may include components having one or more DRAM layers having the interconnect arrangements in accordance with any of the embodiments disclosed herein. The IC device assembly 2300 includes a number of components disposed on a circuit board 2302 (which may be, e.g., a motherboard). The IC device assembly 2300 includes components disposed on a first face 2340 of the circuit board 2302 and an opposing second face 2342 of the circuit board 2302; generally, components may be disposed on one or both faces 2340 and 2342. In particular, any suitable ones of the components of the IC device assembly 2300 may include DRAM layers having the interconnect arrangements in accordance with any of the embodiments disclosed herein; e.g., any of the IC packages discussed below with reference to the IC device assembly 2300 may take the form of any of the embodiments of the IC package 2200 discussed above with reference to FIG. 17 (e.g., may include one or more DRAM layers having the interconnect arrangements described herein provided on a die 2256).

In some embodiments, the circuit board 2302 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2302. In other embodiments, the circuit board 2302 may be a non-PCB substrate.

The IC device assembly 2300 illustrated in FIG. 18 includes a package-on-interposer structure 2336 coupled to the first face 2340 of the circuit board 2302 by coupling components 2316. The coupling components 2316 may electrically and mechanically couple the package-on-interposer structure 2336 to the circuit board 2302, and may include solder balls (e.g., as shown in FIG. 18), male and female portions of a socket, an adhesive, an underfill material, and/or any other suitable electrical and/or mechanical coupling structure.

The package-on-interposer structure 2336 may include an IC package 2320 coupled to an interposer 2304 by coupling components 2318. The coupling components 2318 may take any suitable form for the application, such as the forms discussed above with reference to the coupling components 2316. The IC package 2320 may be or include, for example, a die (the die 2102 of FIG. 16), an IC device, or any other suitable component. In particular, the IC package 2320 may include one or more DRAM layers having the interconnect arrangements as described herein. Although a single IC package 2320 is shown in FIG. 18, multiple IC packages may be coupled to the interposer 2304; indeed, additional interposers may be coupled to the interposer 2304. The interposer 2304 may provide an intervening substrate used to bridge the circuit board 2302 and the IC package 2320. Generally, the interposer 2304 may spread a connection to a wider pitch or reroute a connection to a different connection. For example, the interposer 2304 may couple the IC package 2320 (e.g., a die) to a BGA of the coupling components 2316 for coupling to the circuit board 2302. In the embodiment illustrated in FIG. 18, the IC package 2320 and the circuit board 2302 are attached to opposing sides of the interposer 2304; in other embodiments, the IC package 2320 and the circuit board 2302 may be attached to a same side of the interposer 2304. In some embodiments, three or more components may be interconnected by way of the interposer 2304.

The interposer 2304 may be formed of an epoxy resin, a fiberglass-reinforced epoxy resin, a ceramic material, or a polymer material such as polyimide. In some implementations, the interposer 2304 may be formed of alternate rigid or flexible materials that may include the same materials described above for use in a semiconductor substrate, such as silicon, germanium, and other group III-V and group IV materials. The interposer 2304 may include metal interconnects 2308 and vias 2310, including but not limited to through-silicon vias (TSVs) 2306. The interposer 2304 may further include embedded devices 2314, including both passive and active devices. Such devices may include, but are not limited to, capacitors, decoupling capacitors, resistors, inductors, fuses, diodes, transformers, sensors, electrostatic discharge (ESD) protection devices, and memory devices. More complex devices such as radio frequency (RF) devices, power amplifiers, power management devices, antennas, arrays, sensors, and microelectromechanical systems (MEMS) devices may also be formed on the interposer 2304. The package-on-interposer structure 2336 may take the form of any of the package-on-interposer structures known in the art.

The IC device assembly 2300 may include an IC package 2324 coupled to the first face 2340 of the circuit board 2302 by coupling components 2322. The coupling components 2322 may take the form of any of the embodiments discussed above with reference to the coupling components 2316, and the IC package 2324 may take the form of any of the embodiments discussed above with reference to the IC package 2320.

The IC device assembly 2300 illustrated in FIG. 18 includes a package-on-package structure 2334 coupled to the second face 2342 of the circuit board 2302 by coupling components 2328. The package-on-package structure 2334 may include an IC package 2326 and an IC package 2332 coupled together by coupling components 2330 such that the IC package 2326 is disposed between the circuit board 2302 and the IC package 2332. The coupling components 2328 and 2330 may take the form of any of the embodiments of the coupling components 2316 discussed above, and the IC packages 2326 and 2332 may take the form of any of the embodiments of the IC package 2320 discussed above. The package-on-package structure 2334 may be configured in accordance with any of the package-on-package structures known in the art.

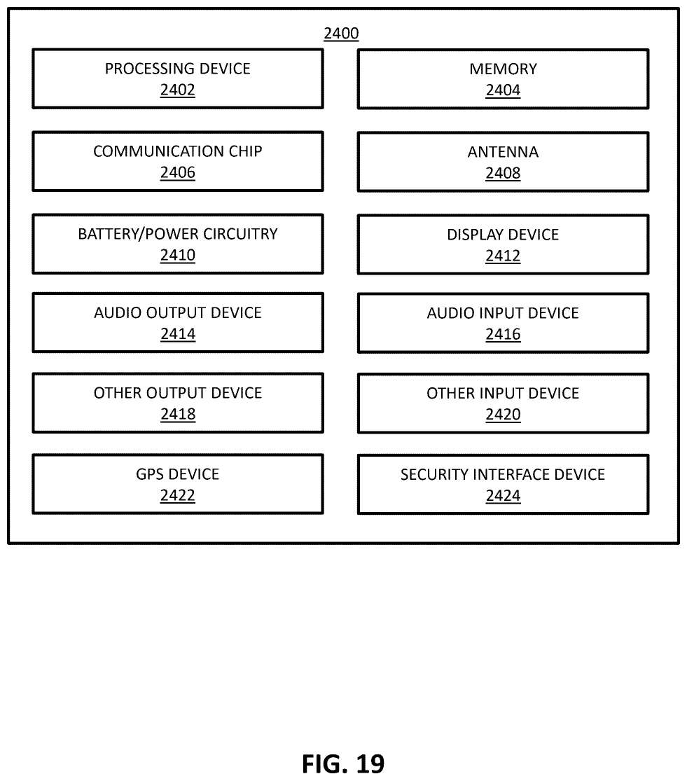

FIG. 19 is a block diagram of an example computing device 2400 that may include one or more components including one or more IC devices with one or more DRAM layers having the interconnect arrangements in accordance with any of the embodiments disclosed herein. For example, any suitable ones of the components of the computing device 2400 may include a die (e.g., the die 2102 of FIG. 16) having one or more DRAM layers having the interconnect arrangements as described herein. Any one or more of the components of the computing device 2400 may include, or be included in, an IC package 2200 of FIG. 17 or an IC device 2300 of FIG. 18.

A number of components are illustrated in FIG. 19 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single system-on-a-chip (SoC) die.

Additionally, in various embodiments, the computing device 2400 may not include one or more of the components illustrated in FIG. 19, but the computing device 2400 may include interface circuitry for coupling to the one or more components. For example, the computing device 2400 may not include a display device 2412, but may include display device interface circuitry (e.g., a connector and driver circuitry) to which a display device 2412 may be coupled. In another set of examples, the computing device 2400 may not include an audio input device 2416 or an audio output device 2414, but may include audio input or output device interface circuitry (e.g., connectors and supporting circuitry) to which an audio input device 2416 or audio output device 2414 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The computing device 2400 may include a memory 2404, which may itself include one or more memory devices such as volatile memory (e.g., DRAM), nonvolatile memory (e.g., read-only memory (ROM)), flash memory, solid state memory, and/or a hard drive. In some embodiments, the memory 2404 may include memory that shares a die with the processing device 2402. This memory may be used as cache memory and may include embedded DRAM (eDRAM) or spin transfer torque magnetic random-access memory (STT-MRAM).

In some embodiments, the computing device 2400 may include a communication chip 2406 (e.g., one or more communication chips). For example, the communication chip 2406 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2406 may implement any of a number of wireless standards or protocols, including but not limited to Institute for Electrical and Electronic Engineers (IEEE) standards including Wi-Fi (IEEE 1402.11 family), IEEE 1402.16 standards (e.g., IEEE 1402.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 1402.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 1402.16 standards. The communication chip 2406 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2406 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2406 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2406 may operate in accordance with other wireless protocols in other embodiments. The computing device 2400 may include an antenna 2408 to facilitate wireless communications and/or to receive other wireless communications (such as AM or FM radio transmissions).

In some embodiments, the communication chip 2406 may manage wired communications, such as electrical, optical, or any other suitable communication protocols (e.g., the Ethernet). As noted above, the communication chip 2406 may include multiple communication chips. For instance, a first communication chip 2406 may be dedicated to shorter-range wireless communications such as Wi-Fi or Bluetooth, and a second communication chip 2406 may be dedicated to longer-range wireless communications such as global positioning system (GPS), EDGE, GPRS, CDMA, WiMAX, LTE, EV-DO, or others. In some embodiments, a first communication chip 2406 may be dedicated to wireless communications, and a second communication chip 2406 may be dedicated to wired communications.

The computing device 2400 may include a battery/power circuitry 2410. The battery/power circuitry 2410 may include one or more energy storage devices (e.g., batteries or capacitors) and/or circuitry for coupling components of the computing device 2400 to an energy source separate from the computing device 2400 (e.g., AC line power).

The computing device 2400 may include a display device 2412 (or corresponding interface circuitry, as discussed above). The display device 2412 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2414 (or corresponding interface circuitry, as discussed above). The audio output device 2414 may include any device that generates an audible indicator, such as speakers, headsets, or earbuds, for example.

The computing device 2400 may include an audio input device 2416 (or corresponding interface circuitry, as discussed above). The audio input device 2416 may include any device that generates a signal representative of a sound, such as microphones, microphone arrays, or digital instruments (e.g., instruments having a musical instrument digital interface (MIDI) output).

The computing device 2400 may include an other output device 2418 (or corresponding interface circuitry, as discussed above). Examples of the other output device 2418 may include an audio codec, a video codec, a printer, a wired or wireless transmitter for providing information to other devices, or an additional storage device.

The computing device 2400 may include an other input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may include a GPS device 2422 (or corresponding interface circuitry, as discussed above). The GPS device 2422 may be in communication with a satellite-based system and may receive a location of the computing device 2400, as known in the art.

The computing device 2400 may include a security interface device 2424. The security interface device 2424 may include any device that provides security features for the computing device 2400 or for any individual components therein (e.g., for the processing device 2402 or for the memory 2404). Examples of security features may include authorization, access to digital certificates, access to items in keychains, etc. Examples of the security interface device 2424 may include a software firewall, a hardware firewall, an antivirus, a content filtering device, or an intrusion detection device.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

### Select Examples

The following paragraphs provide various examples of the embodiments disclosed herein.
Example 1 provides an integrated circuit (IC) device, including a memory region including a plurality of columns of memory cells, where a first column is adjacent to a second column, the first and second column arranged at a first pitch; an interconnect region including vias arranged at a second pitch, the second pitch greater than the first pitch, where a first via is a greater distance from the memory region than a second via; and a plurality of bit lines (BLs), each BL extending across one of the columns of memory cells and into the interconnect region, where a first BL is coupled between the first column and the first via, and a second BL is coupled between the second column and the second via.
Example 2 provides the IC device of example 1, further including a plurality of word lines (WLs), the WLs extending across the memory region in a direction perpendicular to the BLs.
Example 3 provides the IC device of example 2, where the WLs are arranged at a third pitch, and the IC device further includes a second interconnect region including vias arranged at a fourth pitch, the fourth pitch greater than the third pitch.
Example 4 provides the IC device of example 2 or 3, where one of the WLs is coupled to a first memory cell in the first column and to a second memory cell in the second column.
Example 5 provides the IC device of any of examples 1-4, where an area of the interconnect region is greater than or equal to N_{col}*P², where N_{col} is a number of columns in the plurality of columns, and P is the second pitch.
Example 6 provides the IC device of any of examples 1-5, where the IC device includes a first memory layer including the plurality of columns of memory cells, the interconnect region, and the plurality of BLs; and a second memory layer including a second memory region including a second plurality of columns of memory cells; a second interconnect region; and a second plurality of BLs.
Example 7 provides the IC device of example 6, where the first via and the second via extend through the first memory layer and the second memory layer, and the second interconnect region includes the first via and the second via.
Example 8 provides the IC device of example 6, where the first via is a first distance from the memory region of the first memory layer, the second via is a second distance from the memory region of the first memory layer, and the second interconnect region includes a third via at a third distance from the second memory region, the third distance greater than the first distance or the second distance.
Example 9 provides the IC device of one of examples 6-8, further including a hybrid bonding interface between the first memory layer and the second memory layer.
Example 10 provides an integrated circuit (IC) device, including a first memory layer including a first memory region and a first interconnect region, the first interconnect region a first distance from the first memory region, the first interconnect region including a first pair of adjacent vias arranged at a first pitch; and a second memory layer including a second memory region and a second interconnect region, the second interconnect region a second distance from the second memory region, where the second distance is greater than the first distance, the first interconnect region including a second pair of adjacent vias arranged at a second pitch greater than the first pitch.
Example 11 provides the IC device of example 10, further including a hybrid bonding layer between the first memory layer and the second memory layer.
Example 12 provides the IC device of example 10 or 11, where the second pair of vias extends through the first memory layer.
Example 13 provides the IC device of example 10 or 11, where the second pair of vias is coupled to a third pair of vias in the first memory layer.
Example 14 provides the IC device of any of examples 10-13, where the first pair of adjacent vias includes a first via arranged the first distance from the first memory region; and a second via arranged a third distance from the first memory region, the third distance greater than the first distance.
Example 15 provides the IC device of any of examples 10-14, where one of the first pair of adjacent vias has a first width, one of the second pair of adjacent vias has a second width, and the second width is greater than the first width.
Example 16 provides the IC device of any of examples 10-15, further including a third memory layer including a third memory region and a third interconnect region, the third interconnect region a third distance from the third memory region, where the third distance is greater than the second distance.
Example 17 provides the IC device of any of examples 10-16, where the IC device is coupled to a packaging component.
Example 18 provides an integrated circuit (IC) package including a memory region including a number of bit lines (BLs) arranged at a BL pitch; and an interconnect region including vias arranged at a via pitch, the via pitch greater than the BL pitch; where the interconnect region has an area greater than or equal to the number of BLs times the square of the via pitch; and at least a portion of the vias are coupled to a circuit board.
Example 19 provides the IC package of example 18, where the via pitch is at least twice the BL pitch.
Example 20 provides the IC package of example 18 or 19, where the via pitch is a first via pitch, the IC package further including a second interconnect region including vias arranged at a second via pitch greater than the first via pitch.
Example 21 provides an IC package that includes an IC die, including one or more of the memory/IC devices according to any one of the preceding examples. The IC package may also include a further component, coupled to the IC die.
Example 22 provides the IC package according to example 21, where the further component is one of a package substrate, a flexible substrate, or an interposer.
Example 23 provides the IC package according to examples 21 or 22, where the further component is coupled to the IC die via one or more first level interconnects.
Example 24 provides the IC package according to example 23, where the one or more first level interconnects include one or more solder bumps, solder posts, or bond wires.
Example 25 provides a computing device that includes a circuit board; and an IC die coupled to the circuit board, where the IC die includes one or more of the memory/IC devices according to any one of the preceding examples (e.g., memory/IC devices according to any one of examples 1-20), and/or the IC die is included in the IC package according to any one of the preceding examples (e.g., the IC package according to any one of examples 21-24).
Example 26 provides the computing device according to example 25, where the computing device is a wearable computing device (e.g., a smart watch) or hand-held computing device (e.g., a mobile phone).
Example 27 provides the computing device according to examples 25 or 26, where the computing device is a server processor.
Example 28 provides the computing device according to examples 25 or 26, where the computing device is a motherboard.
Example 29 provides the computing device according to any one of examples 25-28, where the computing device further includes one or more communication chips and an antenna.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) device, comprising:
a memory region comprising a plurality of columns of memory cells, wherein a first column is adjacent to a second column, the first and second column arranged at a first pitch;
an interconnect region comprising a plurality of vias arranged at a second pitch, the second pitch greater than the first pitch, wherein a first via is a greater distance from the memory region than a second via; and
a plurality of bit lines (BLs), each BL extending across one of the columns of memory cells and into the interconnect region, wherein a first BL is coupled between the first column and the first via, and a second BL is coupled between the second column and the second via.

2. The IC device of claim 1, further comprising a plurality of word-lines (WLs), the WLs extending across the memory region in a direction perpendicular to the BLs.

3. The IC device of claim 2, wherein the WLs are arranged at a third pitch, and the IC device further comprises:
a second interconnect region comprising vias arranged at a fourth pitch, the fourth pitch greater than the third pitch.

4. The IC device of claim 2, wherein one of the WLs is coupled to a first memory cell in the first column and to a second memory cell in the second column.

5. The IC device of claim 1, wherein an area of the interconnect region is greater than or equal to N_{col}*P², wherein N_{col} is a number of columns in the plurality of columns, and P is the second pitch.

6. The IC device of claim 1, wherein the IC device comprises:
a first memory layer comprising the plurality of columns of memory cells, the interconnect region, and the plurality of BLs; and
a second memory layer comprising:
a second memory region comprising a second plurality of columns of memory cells;
a second interconnect region; and
a second plurality of BLs.

7. The IC device of claim 6, wherein the first via and the second via extend through the first memory layer and the second memory layer, and the second interconnect region comprises the first via and the second via.

8. The IC device of claim 6, wherein the first via is a first distance from the memory region of the first memory layer, the second via is a second distance from the memory region of the first memory layer, and the second interconnect region comprises a third via at a third distance from the second memory region, the third distance greater than the first distance or the second distance.

9. The IC device of claim 6, further comprising a hybrid bonding interface between the first memory layer and the second memory layer.

10. An integrated circuit (IC) device, comprising:
a first memory layer comprising a first memory region and a first interconnect region, the first interconnect region a first distance from the first memory region, the first interconnect region comprising a first pair of adjacent vias arranged at a first pitch; and
a second memory layer comprising a second memory region and a second interconnect region, the second interconnect region a second distance from the second memory region, wherein the second distance is greater than the first distance, the first interconnect region comprising a second pair of adjacent vias arranged at a second pitch greater than the first pitch.

11. The IC device of claim 10, further comprising a hybrid bonding layer between the first memory layer and the second memory layer.

12. The IC device of claim 10, wherein the second pair of vias extends through the first memory layer.

13. The IC device of claim 10, wherein the second pair of vias is coupled to a third pair of vias in the first memory layer.

14. The IC device of claim 10, wherein the first pair of adjacent vias comprises:
a first via arranged the first distance from the first memory region; and
a second via arranged a third distance from the first memory region, the third distance greater than the first distance.

15. The IC device of claim 10, wherein one of the first pair of adjacent vias has a first width, one of the second pair of adjacent vias has a second width, and the second width is greater than the first width.

16. The IC device of claim 10, further comprising a third memory layer comprising a third memory region and a third interconnect region, the third interconnect region a third distance from the third memory region, wherein the third distance is greater than the second distance.

17. The IC device of claim 10, wherein the IC device is coupled to a packaging component.

18. An integrated circuit (IC) package comprising:
a memory region comprising a number of bit lines (BLs) arranged at a BL pitch; and
an interconnect region comprising vias arranged at a via pitch, the via pitch greater than the BL pitch;
wherein the interconnect region has an area greater than or equal to the number of BLs times a square of the via pitch, and at least a portion of the vias are coupled to a circuit board.

19. The IC package of claim 18, wherein the via pitch is at least twice the BL pitch.

20. The IC package of claim 18, wherein the via pitch is a first via pitch, the IC package further comprising a second interconnect region comprising vias arranged at a second via pitch greater than the first via pitch.
